(19) United States
(12) Patent Application Publication
(10) Pub. No.: US 2026/0282573 A1
(43) Pub. Date: Sep. 17, 2026

(54) PHOTODETECTION DEVICE, ELECTRONIC EQUIPMENT, AND SEMICONDUCTOR DEVICE

(71) Applicant: SONY SEMICONDUCTOR SOLUTIONS CORPORATION, KANAGAWA (JP)

(72) Inventor: KENTARO IMAMIZU, KUMAMOTO (JP)

(21) Appl. No.: 19/469,051

(22) PCT Filed: Feb. 16, 2024
(86) PCT No.: PCT/JP2024/005610

§ 371 Date: Sep. 25, 2025

(30) Foreign Application Priority Data
Apr. 11, 2023 (JP) 2023-064268

(51) Int. Cl. H10F 39/00; H10F 39/18

(52) U.S. Cl. CPC H10F 39/80373; H10F 39/182; H10F 39/807; H10F 39/811

(57) ABSTRACT

A photodetection device capable of improving a degree of freedom in wiring layout is provided. Specifically, the photodetection device includes a plurality of photoelectric conversion units formed in a two-dimensional array on a semiconductor substrate and a plurality of pixel transistors. In addition, the plurality of pixel transistors includes a first transfer transistor having a first gate electrode facing a first channel formation region and a second transfer transistor having a second gate electrode facing a second channel formation region and electrically connected to the first gate electrode. Further, in a case where a first voltage is applied to the first and second gate electrodes, a channel is formed only in the first channel formation region, and in a case where a second voltage higher than the first voltage is applied to the first and second gate electrodes, a channel is formed in both the first and second channel formation regions.

### TECHNICAL FIELD

The present technology (technology according to the present disclosure) relates to a photodetection device, electronic equipment, and a semiconductor device.

### BACKGROUND ART

In related art, for example, there has been proposed a photodetection device including a plurality of photoelectric conversion units (photodiodes) formed in a two-dimensional array on a semiconductor substrate, a charge accumulation region (floating diffusion) formed on the semiconductor substrate apart from the photoelectric conversion units and shared by 2×2 photoelectric conversion units, and a plurality of transfer transistors formed for each of the photoelectric conversion units and transferring charges generated by the photoelectric conversion units to the charge accumulation region (see, for example, Patent Document 1). The photodetection device described in Patent Document 1 transfers charges of one photoelectric conversion unit out of 2×2 photoelectric conversion units to perform standard dynamic range (SDR) imaging in a bright place, and simultaneously transfers charges of two or more photoelectric conversion units to perform high dynamic range (HDR) imaging in a dark place.

### CITATION LIST

### Patent Document

Patent Document 1: Japanese Patent Application Laid-Open No. 2012-104979

### SUMMARY OF THE INVENTION

### Problems to be Solved by the Invention

However, in the photodetection device described in Patent Document 1, gate electrodes as many as the photoelectric conversion units are required, and thus, wirings as many as the photoelectric conversion units are also required to supply gate voltages to the gate electrodes. Thus, there is a possibility that the number of wirings increases and a degree of freedom in wiring layout decreases.

An object of the present disclosure is to provide a photodetection device, electronic equipment, and a semiconductor device capable of improving a degree of freedom in wiring layout.

### Solutions to Problems

A photodetection device of the present disclosure includes (a) a semiconductor substrate, (b) a plurality of photoelectric conversion units formed in a two-dimensional array on the semiconductor substrate, and (c) a plurality of transistors, in which (d) a plurality of pixel transistors includes a first transistor having a first gate electrode facing a first channel formation region, and a second transistor having a second gate electrode facing a second channel formation region and electrically connected to the first gate electrode, (e) in a case where a first voltage is applied to the first gate electrode and the second gate electrode, a channel is formed only in the first channel formation region, and (f) in a case where a second voltage higher than the first voltage is applied to the first gate electrode and the second gate electrode, a channel is formed in both the first channel formation region and the second channel formation region.

Another electronic equipment of the present disclosure includes a photodetection device that includes (a) a semiconductor substrate, (b) a plurality of photoelectric conversion units formed in a two-dimensional array on the semiconductor substrate, (c) and a plurality of transistors, in which (d) a plurality of pixel transistors includes a first transistor having a first gate electrode facing a first channel formation region and a second transistor having a second gate electrode facing a second channel formation region and electrically connected to the first gate electrode, (e) in a case where a first voltage is applied to the first gate electrode and the second gate electrode, a channel is formed only in the first channel formation region, and (f) in a case where a second voltage higher than the first voltage is applied to the first gate electrode and the second gate electrode, a channel is formed in both the first channel formation region and the second channel formation region.

Another semiconductor device of the present disclosure includes (a) a first transistor having a first gate electrode facing a first channel formation region, and (b) a second transistor having a second gate electrode facing a second channel formation region and electrically connected to the first gate electrode, in which (c) in a case where a first voltage is applied to the first gate electrode and the second gate electrode, a channel is formed only in the first channel formation region, and (d) in a case where a second voltage higher than the first voltage is applied to the first gate electrode and the second gate electrode, a channel is formed in both the first gate electrode and the second channel formation region.

### BRIEF DESCRIPTION OF DRAWINGS

FIG. 1 is a view illustrating an overall configuration of a solid-state imaging device according to a first embodiment.

FIG. 2 is a view illustrating a circuit configuration of a pixel.

FIG. 3 is a view illustrating a planar configuration of the solid-state imaging device in a case where a region A in FIG. 1 is viewed from a front surface side of a semiconductor substrate.

FIG. 4 is a view illustrating a cross-sectional configuration of the solid-state imaging device taken along a line B-B′ in FIG. 3.

FIG. 5 is a view illustrating a planar configuration of the solid-state imaging device in a case where a first gate electrode and a second gate electrode are omitted from FIG. 3.

FIG. 6 is a view illustrating a cross-sectional configuration of the solid-state imaging device taken along a line C-C′ in FIG. 3.

FIG. 7 is a view illustrating operation of a first transfer transistor and a second transfer transistor.

FIG. 8 is a view illustrating operation of the first transfer transistor and the second transfer transistor.

FIG. 9 is a view illustrating a planar configuration of a solid-state imaging device according to a comparative example.

FIG. 10 is a view illustrating a cross-sectional configuration of a solid-state imaging device according to a second embodiment.

FIG. 11 is a view illustrating a planar configuration of a solid-state imaging device according to Modification (2).

FIG. 12 is a view illustrating a cross-sectional configuration of the solid-state imaging device taken along a line D-D′ in FIG. 11.

FIG. 13 is a view illustrating a planar configuration of a solid-state imaging device according to Modification (3).

FIG. 14 is a view illustrating a planar configuration of a solid-state imaging device according to modification (4).

FIG. 15 is a view illustrating a case where Modification (4) is applied to the solid-state imaging device according to the first embodiment.

FIG. 16 is a view illustrating a case where Modification (4) is applied to the solid-state imaging device according to the second embodiment.

FIG. 17 is a view illustrating an example of a sensor pixel and a readout circuit.

FIG. 18 is a view illustrating an example of a schematic configuration of the solid-state imaging device according to the present modification.

FIG. 19 is a view illustrating a circuit configuration of a pixel according to Modification (5).

FIG. 20 is a block diagram illustrating a configuration example of electronic equipment.

FIG. 21 is a block diagram illustrating an example of a schematic configuration of a vehicle control system.

FIG. 22 is an explanatory diagram illustrating an example of positions where an outside-vehicle information detecting unit and an imaging section are provided.

FIG. 23 is a view illustrating an example of a schematic configuration of an endoscopic surgery system.

FIG. 24 is a block diagram illustrating an example of a functional configuration of a camera head and a CCU.

### MODE FOR CARRYING OUT THE INVENTION

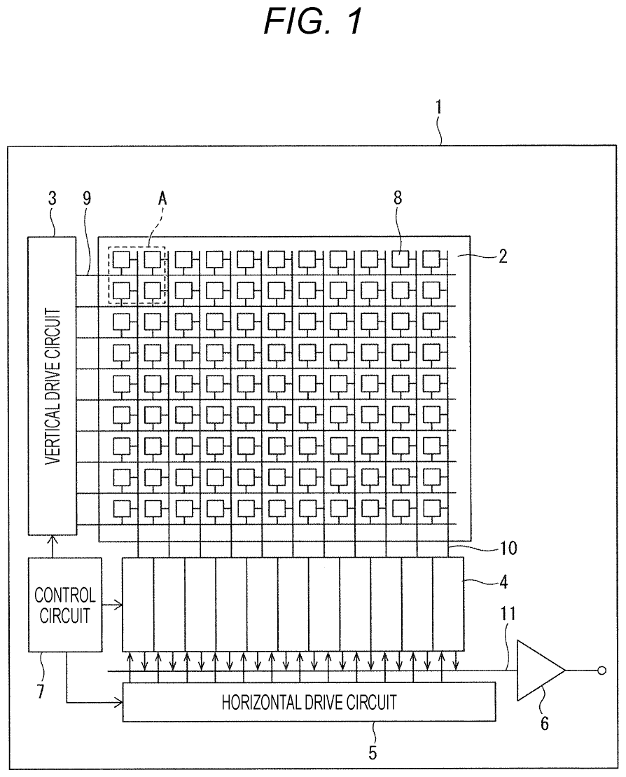

Hereinafter, examples of a photodetection device, electronic equipment, and a semiconductor device according to embodiments of the present disclosure will be described with reference to FIGS. 1 to 24. The embodiments of the present disclosure will be described in the following order. Note that, the present disclosure is not limited to the following examples. Furthermore, the effects described in the present specification are illustrative and not restrictive, and there may be additional effects.
1. First Embodiment: Solid-State Imaging Device
1-1 Overall Configuration of Solid-State Imaging Device
1-2 Circuit Configuration of Pixel
1-3 Configuration of Main Part
2. Second Embodiment: Solid-State Imaging Device
2-1 Configuration of Main Part
2-2 Modifications
3. Third Embodiment: Electronic Equipment
4. Example of Application to Mobile Body
5. Example of Application to Endoscopic Surgery System

### 1. First Embodiment

### [1-1 Overall Configuration of Solid-State Imaging Device]

A solid-state imaging device 1 (in a broad sense, a “photodetection device”) according to a first embodiment of the present disclosure will be described. FIG. 1 is a view illustrating an overall configuration of the solid-state imaging device 1 according to the first embodiment.

The solid-state imaging device 1 in FIG. 1 is a back-illuminated complementary metal oxide semiconductor (CMOS) image sensor. As illustrated in FIG. 20, the solid-state imaging device 1 (photodetection device 103) captures image light (incident light) from a subject via an optical system 102, converts an amount of the incident light forming an image on a light receiving surface into an electric signal in units of pixels, and outputs the electric signal as a pixel signal.

As illustrated in FIG. 1, the solid-state imaging device 1 includes a pixel region 2 and a peripheral circuit unit. The peripheral circuit unit includes a vertical drive circuit 3, a column signal processing circuit 4, a horizontal drive circuit 5, an output circuit 6, and a control circuit 7.

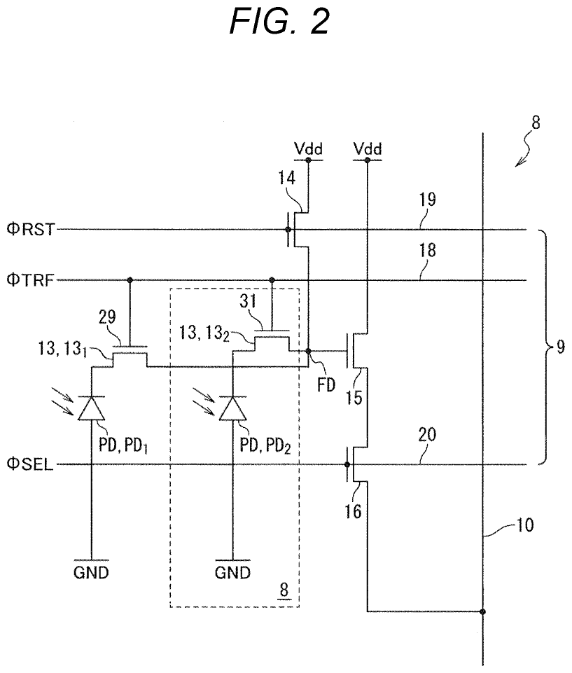

The pixel region 2 includes a plurality of pixels 8 arranged in a two-dimensional array. The pixel 8 includes a photoelectric conversion unit PD (see FIG. 2) that generates charges (for example, electrons) according to the amount of received light, and a plurality of pixel transistors (see FIG. 2) that outputs pixel signals based on the charges generated in the photoelectric conversion unit PD. As the plurality of pixel transistors, a transfer transistor 13, a reset transistor 14, an amplification transistor 15, and a selection transistor 16 can be employed, for example.

The vertical drive circuit 3 includes, for example, a shift register, sequentially selects the pixel 8 in the pixel region 2 row by row by, for example, sequentially outputting a selection pulse φSEL (see FIG. 2) to a pixel drive wiring 9, and outputs a pixel signal of the selected pixel 8 to the column signal processing circuit 4 through a vertical signal line 10. The pixel signal is a signal obtained by charges generated by the photoelectric conversion unit PD.

The column signal processing circuit 4 is provided, for example, for each column of the pixel 8, and performs signal processing on the pixel signal output from the pixel 8 corresponding to one row for each pixel column.

As the signal processing, for example, correlated double sampling (CDS) for removing pixel-specific fixed pattern noise and analog digital (AD) conversion can be employed.

The horizontal drive circuit 5 includes, for example, a shift register, sequentially selects the column signal processing circuit 4 by sequentially outputting a horizontal scanning pulse to the column signal processing circuit 4, and causes the selected column signal processing circuit 4 to output the pixel signal subjected to the signal processing to a horizontal signal line 11.

The output circuit 6 performs signal processing on the pixel signal sequentially output from the column signal processing circuit 4 through the horizontal signal line 11, and outputs the pixel signal. As the signal processing, various types of digital signal processing such as buffering, black level adjustment, and column variation correction can be used.

The control circuit 7 generates a clock signal and a control signal that are references for operation of the vertical drive circuit 3, the column signal processing circuit 4, the horizontal drive circuit 5, and the like, on the basis of a vertical synchronization signal, a horizontal synchronization signal, and a master clock signal (not illustrated). Then, the control circuit 7 outputs the generated clock signal and the control signal to the vertical drive circuit 3, the column signal processing circuit 4, the horizontal drive circuit 5, and the like.

### [1-2 Circuit Configuration of Pixel]

Next, a circuit configuration of the pixel 8 will be described. FIG. 2 is a view illustrating a circuit configuration of the pixel 8.

As illustrated in FIG. 2, the pixel 8 includes a photoelectric conversion unit PD, four pixel transistors (a transfer transistor 13, a reset transistor 14, an amplification transistor 15, and a selection transistor 16), and a floating diffusion (hereinafter, also referred to as a “charge accumulation region FD”). As the transfer transistor 13, the reset transistor 14, the amplification transistor 15, and the selection transistor 16, n-channel MOS transistors can be employed, for example. In addition, the charge accumulation region FD is a region that holds charges (for example, electrons) generated by the photoelectric conversion unit PD. For example, an n-type semiconductor region doped with an n-type impurity can be employed. Furthermore, in the pixel 8, for example, a transfer line 18, a reset line 19, and a selection line 20 are provided in common for each pixel 8 in the same row as the pixel drive wiring 9. One end of each of the transfer line 18, the reset line 19, and the selection line 20 is connected to the vertical drive circuit 3 (see FIG. 1).

The photoelectric conversion unit PD has an anode electrode electrically connected to a reference potential line (for example, ground), and a cathode electrode connected to a gate electrode of the amplification transistor 15 via the transfer transistor 13. The photoelectric conversion unit PD performs photoelectric conversion to generate charges according to the amount of received light.

The transfer transistor 13 is connected between the cathode electrode of the photoelectric conversion unit PD and the charge accumulation region FD. A transfer pulse φTRF for which a high level is active (hereinafter, also referred to as “High active”) is applied to a gate electrode of the transfer transistor 13 via the transfer line 18. As a result of the transfer pulse φTRF being applied to the gate electrode, the transfer transistor 13 is turned on and transfers the charges accumulated in the photoelectric conversion unit PD to the charge accumulation region FD.

Here, as will be described later, gate electrodes (a first gate electrode 29, a second gate electrode 31) of two adjacent transfer transistors 13 (a first transfer transistor 13₁, a second transfer transistor 13₂) are electrically connected to each other. Thus, the first gate electrode 29 and the second gate electrode 31 are electrically connected to the same transfer line 18, and the same transfer pulse φTRF is applied. In addition, the transfer pulse φTRF can be applied with two types of a first voltage Vth1 and a second voltage Vth2 (>Vth1) as high levels. Then, if the first voltage Vth1 or the second voltage Vth2 (that is, a voltage equal to or higher than the first voltage Vth1) is applied to the first gate electrode 29, the first transfer transistor 13₁ is turned on so that the charges accumulated in a first photoelectric conversion unit PD₁ (described later) can be transferred to the charge accumulation region FD. In addition, if the second voltage Vth2 is applied to the second gate electrode 31, the second transfer transistor 13₂ is turned on so that the charges accumulated in a second photoelectric conversion unit PD₂ (described later) can be transferred to the charge accumulation region FD.

The reset transistor 14 has a drain connected to a power supply line Vdd, and a source connected to the charge accumulation region FD. A High active reset pulse φRST is applied to the gate electrode of the reset transistor 14 via the reset line 19 before charges are transferred from the photoelectric conversion unit PD to the charge accumulation region FD by the transfer transistor 13 (the first transfer transistor 131, the second transfer transistor 13₂). As a result of the reset pulse φRST being applied to the gate electrode, the reset transistor 14 is turned on, discards the charges accumulated in the charge accumulation region FD to the power supply line Vdd, and resets the charge accumulation region FD.

The amplification transistor 15 has a gate electrode connected to the charge accumulation region FD, and a drain electrode connected to the power supply line Vdd. Then, after the reset is executed, a signal corresponding to a potential of the charge accumulation region FD after the charges are transferred by the transfer transistor 13 is output as a pixel signal.

The selection transistor 16 has a drain electrode connected to the source electrode of the amplification transistor 15, and a source electrode connected to the vertical signal line 10. A High active selection pulse φSEL is applied to a gate electrode of the selection transistor 16 via a selection line 20. As a result of the selection pulse φSEL being applied to the gate electrode, the selection transistor 16 is turned on and outputs the pixel signal output from the amplification transistor 15 to the vertical signal line 10.

With the above configuration, the pixel transistor (the transfer transistor 13, the reset transistor 14, the amplification transistor 15, the selection transistor 16) outputs a pixel signal based on the charges generated by the photoelectric conversion unit PD. Note that the selection transistor 16 may be omitted.

### [1-3 Configuration of Main Part]

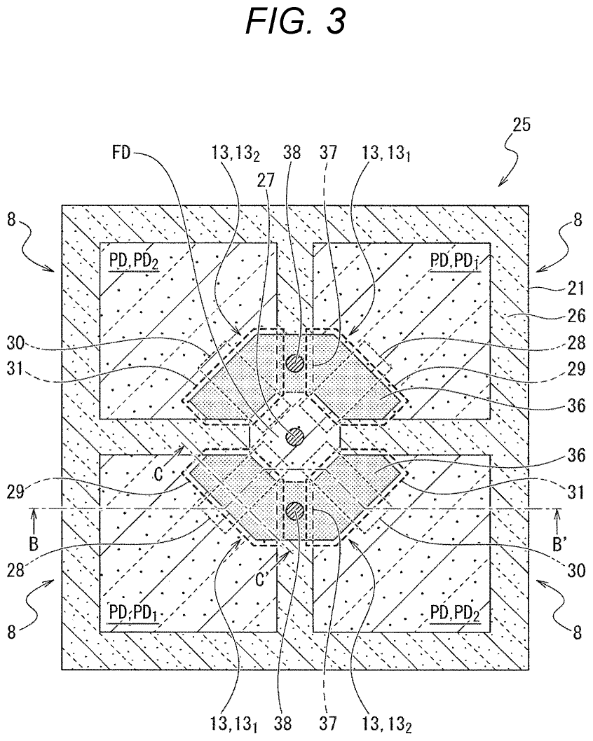

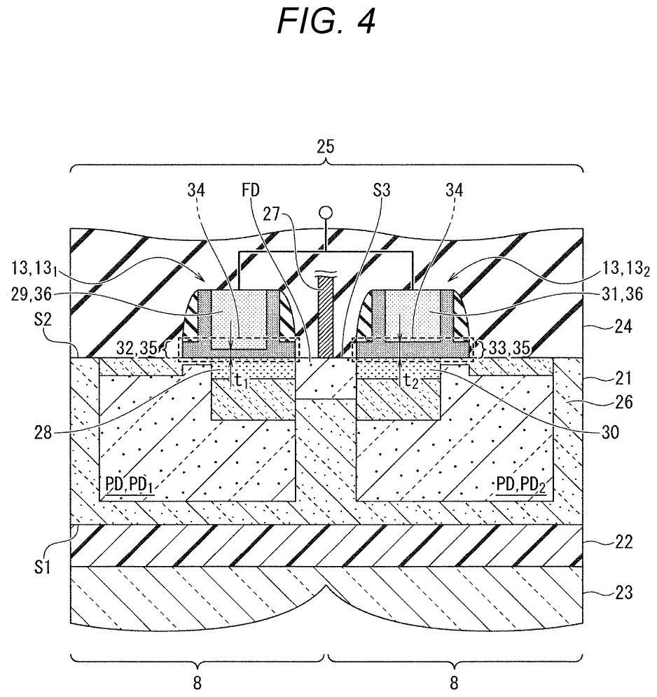

Next, a detailed structure of the solid-state imaging device 1 will be described. FIG. 3 is a view illustrating a planar configuration of the solid-state imaging device 1 in a case where a region A in FIG. 1 is viewed from a front surface side of a semiconductor substrate 21. Furthermore, FIG. 4 is a view illustrating a cross-sectional configuration of the solid-state imaging device 1 taken along a line B-B′ in FIG. 3.

As illustrated in FIG. 4, the solid-state imaging device 1 includes the semiconductor substrate 21, and a color filter 22 and a microlens 23 are stacked in this order on a light receiving surface (hereinafter, also referred to as “back surface S1”) of the semiconductor substrate 21. Note that various films such as a planarization film and an optical black (OPB) film may be arranged between the semiconductor substrate 21 and the color filter 22. Further, a wiring layer 24 is arranged on a surface (in a broad sense, a “first surface”, hereinafter, also referred to as a “front surface S2” opposite to a back surface S1 of the semiconductor substrate 21.

The semiconductor substrate 21 is a substrate including, for example, silicon (Si). As illustrated in FIG. 3, in the semiconductor substrate 21, the photoelectric conversion unit PD is formed in each region corresponding to each pixel 8. In other words, the plurality of photoelectric conversion units PD is arranged in a two-dimensional array on the semiconductor substrate 21. In addition, the plurality of photoelectric conversion units PD has a configuration in which 2×2 photoelectric conversion units PD constitute one block 25, and the plurality of blocks 25 is two-dimensionally arranged. Hereinafter, among the 2×2 photoelectric conversion units PD, lower left and upper right photoelectric conversion units PD in FIG. 3 are also referred to as “first photoelectric conversion units PD₁”, and lower right and upper left photoelectric conversion units PD in FIG. 3 are also referred to as “second photoelectric conversion units PD₂”. In other words, the first photoelectric conversion units PD₁ and the second photoelectric conversion units PD₂ (in a broad sense, “two or more photoelectric conversion units”) are a pair of adjacent photoelectric conversion units PD included in the 2×2 photoelectric conversion units PD. FIG. 3 illustrates a case where the first photoelectric conversion units PD₁ and the second photoelectric conversion units PD₂ are adjacent to each other in the left-right direction. The first photoelectric conversion units PD₁ and the second photoelectric conversion units PD₂ have a p-type semiconductor region and an n-type semiconductor region, constitute a photodiode by a pn junction between the p-type semiconductor region and the n-type semiconductor region, and perform photoelectric conversion on the incident light to generate charges (for example, electrons). Furthermore, the first photoelectric conversion units PD₁ and the second photoelectric conversion units PD₂ accumulate the generated charges in electrostatic capacitance generated in the pn junction.

Furthermore, in a region between the adjacent photoelectric conversion units PD (PD₁, PD₂) of the semiconductor substrate 21, a pixel isolation portion 26 is formed. In other words, the pixel isolation portion 26 is formed in a lattice shape so as to surround each photoelectric conversion unit PD (PD₁, PD₂). The pixel isolation portion 26 is continuously formed from the front surface S2 side to the back surface S1 side of the semiconductor substrate 21. For example, a p-type semiconductor region can be adopted. By the pixel isolation portion 26, a potential barrier can be formed between the adjacent photoelectric conversion units PD (PD₁, PD₂), so that charge transfer between the photoelectric conversion units PD (PD₁, PD₂) is prevented.

Furthermore, on the front surface S2 side of the semiconductor substrate 21, the charge accumulation region FD is formed apart from the photoelectric conversion units PD (PD₁, PD₂). The charge accumulation region FD is formed for each block 25 and is formed in a region of the semiconductor substrate 21 located at the center of the block 25. In other words, the charge accumulation region FD is formed in a region located at the center of the block 25 in the pixel isolation portion 26 in a case of being viewed from a thickness direction of the semiconductor substrate 21, and is shared by 2×2 photoelectric conversion units PD (PD₁, PD₂) constituting the block 25. In other words, it can be said that the charge accumulation region FD is shared by two or more photoelectric conversion units PD (PD₁, PD₂) . In addition, a surface of the charge accumulation region FD on the wiring layer 24 side (hereinafter, also referred to as an “exposed surface S3”) is exposed to the front surface S2. The charge accumulation region FD is connected to a contact 27 arranged at a position facing the exposed surface S3, and is electrically connected to a pixel transistor (for example, the gate electrode, or the like, of the amplification transistor 15 illustrated in FIG. 2) via the contact 27, a wiring of the wiring layer 24, and the like.

Furthermore, as illustrated in FIG. 4, a plurality of transfer transistors 13 is formed on the front surface S2 side of the semiconductor substrate 21. The plurality of transfer transistors 13 includes a first transfer transistor 13₁ (in a broad sense, a “first transistor”) that transfers the charges generated by the first photoelectric conversion unit PD₁ to the charge accumulation region FD, and a second transfer transistor 13₂ (in a broad sense, a “second transistor”) that transfers the charges generated by the second photoelectric conversion unit PD₂ to the charge accumulation region FD. The first transfer transistor 13₁ includes a first gate electrode 29 facing a first channel formation region 28. The first channel formation region 28 is a p-type semiconductor region formed in a region between the first photoelectric conversion unit PD₁ and the charge accumulation region FD on the back surface S1 side of the semiconductor substrate 21 and doped with a p-type impurity (for example, boron (B)). In addition, the first gate electrode 29 is an electrode formed on the front surface S2 of the semiconductor substrate 21 via s first gate insulating film 32 so as to face the first channel formation region 28 and includes doped polysilicon (Poly-Si), or the like.

In addition, the second transfer transistor 13₂ includes a second gate electrode 31 facing the second channel formation region 30. The second channel formation region 30 is a p-type semiconductor region formed in a region between the second photoelectric conversion unit PD₂ and the charge accumulation region FD on the front surface S2 side of the semiconductor substrate 21 and doped with a p-type impurity. In addition, the second gate electrode 31 is an electrode formed on the front surface S2 of the semiconductor substrate 21 via a second gate insulating film 33 so as to face the second channel formation region 30 and includes doped polysilicon, or the like. Further, the first channel formation region 28 and the second channel formation region 30 have the same impurity concentration.

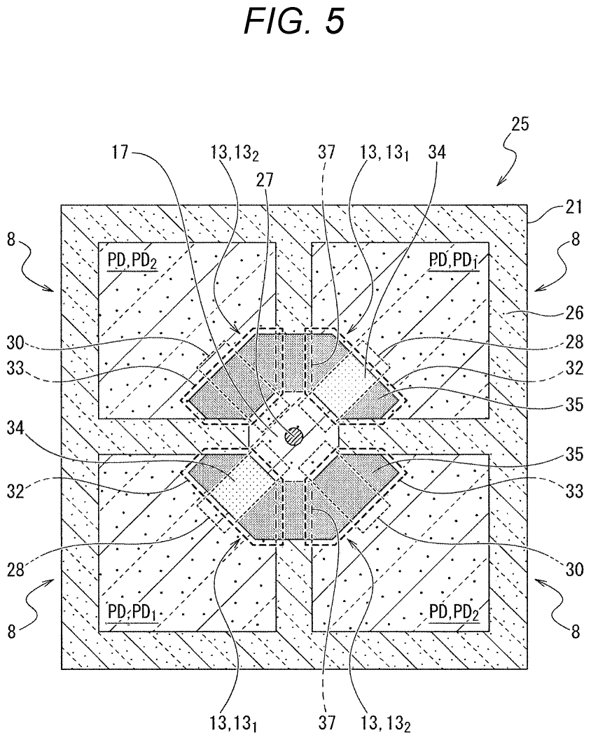

Further, a thickness t₁ of at least a portion of the first gate insulating film 32 is smaller than a thickness t₂ of each portion of the second gate insulating film 33. In FIG. 4, in a case of being viewed from the thickness direction of the semiconductor substrate 21, the thickness t₁ of a band-shaped region 34 (see FIG. 5) of the first gate insulating film 32 extending from the first photoelectric conversion unit PD₁ side to the charge accumulation region FD side is smaller than the thickness t₂ of each portion of the second gate insulating film 33 (t₁<t₂). FIG. 5 is a view illustrating a planar configuration of the solid-state imaging device 1 in a case where the first gate electrode 29 and the second gate electrode 31 are omitted from FIG. 3. A difference between the thicknesses t₁ and t₂ is set such that a difference between a voltage (first voltage Vth1) at which a channel is formed in the first channel formation region 28 and a voltage (second voltage Vth2>Vth1) at which a channel is formed in the second channel formation region 30 is equal to or larger than a predetermined value (for example, 0.5 V). In other words, the thickness t₁ of at least a portion of the first gate insulating film 32 is smaller than the thickness t₂ of each portion of the second gate insulating film 33 so that the difference between the first voltage Vth1 and the second voltage Vth2 is equal to or larger than the predetermined value.

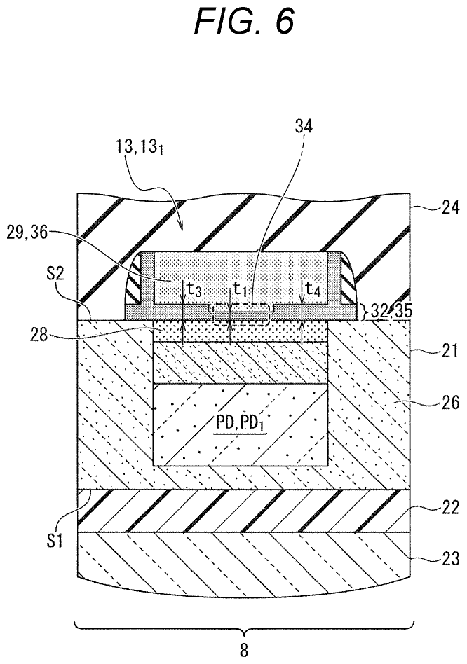

Further, as illustrated in FIGS. 5 and 6, thicknesses t₃ and t₄ of the remaining regions of the first gate insulating film 32 located on one side and the other side sandwiching the band-shaped region 34 are larger than the thickness t₁ of the band-shaped region 34 (t₃, t₄>t₁). FIG. 6 is a view illustrating a cross-sectional configuration of the solid-state imaging device 1 taken along a line C-C′ in FIG. 3. By setting t₃, t₄>t₁, it is possible to suppress occurrence of dielectric breakdown at portions (for example, portions in contact with the lower left corner and the lower right corner of the first gate electrode 29 in FIG. 6) of the first gate insulating film 32 to which a high voltage is applied due to electric field concentration.

As illustrated in FIG. 3, the first gate electrode 29 and the second gate electrode 31 are continuous. In other words, the first gate electrode 29 and the second gate electrode 31 are constituted with one gate electrode 36 and are electrically connected to each other. Similarly, as illustrated in FIG. 5, the first gate insulating film 32 and the second gate insulating film 33 are constituted with one gate insulating film 35 having the same shape as the gate electrode 36. FIGS. 3 and 5 illustrate a case where the gate insulating film 35 and the gate electrode 36 are formed in a band shape along an outer periphery of the exposed surface S3 of the charge accumulation region FD so as to continuously cover the first channel formation region 28 and the second channel formation region 30. More specifically, each of the gate insulating film 35 and the gate electrode 36 is continuously formed across a region (hereinafter, also referred to as an “isolation region 37”) located between the first photoelectric conversion unit PD₁ and the second photoelectric conversion unit PD₂ in the pixel isolation portion 26 in a case of being viewed from the thickness direction of the semiconductor substrate 21.

In addition, the gate electrode 36 is connected to a contact 38 (see FIG. 3) at a position overlapping the isolation region 37 in a case of being viewed from the thickness direction of the semiconductor substrate 21, and is electrically connected to the is transfer line 18 (see FIG. 2) via the contact 38, a wiring of the wiring layer 24, and the like.

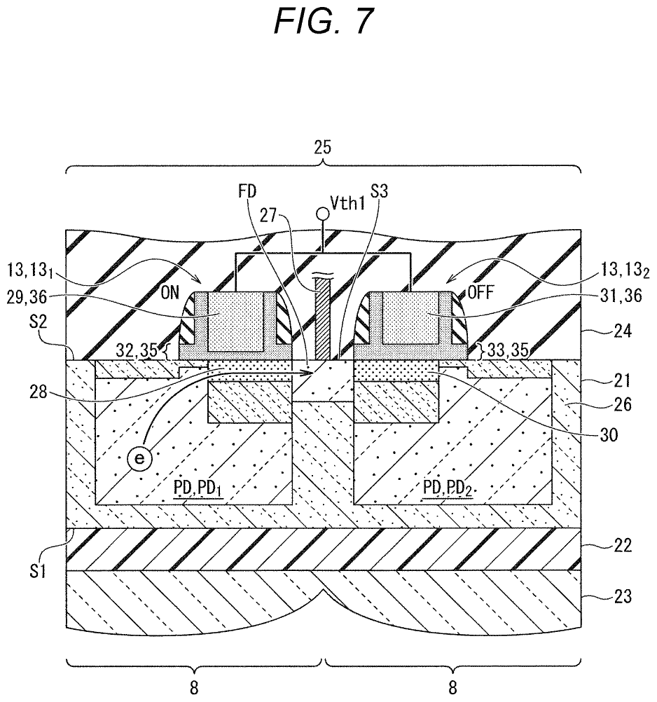

With the above configuration, in the first transfer transistor 13₁ and the second transfer transistor 13₂, for example, as illustrated in FIG. 7, if the first voltage Vth1 (low voltage) is applied to the first gate electrode 29 and the second gate electrode 31 as the transfer pulse φTRF, the first transfer transistor 13₁ is turned on, the second transfer transistor 13₂ is turned off, and a channel is formed only in the first channel formation region 28 facing the first gate electrode 29. Then, the charges accumulated in the first photoelectric conversion unit PD₁ are transferred to the charge accumulation region FD through the formed channel.

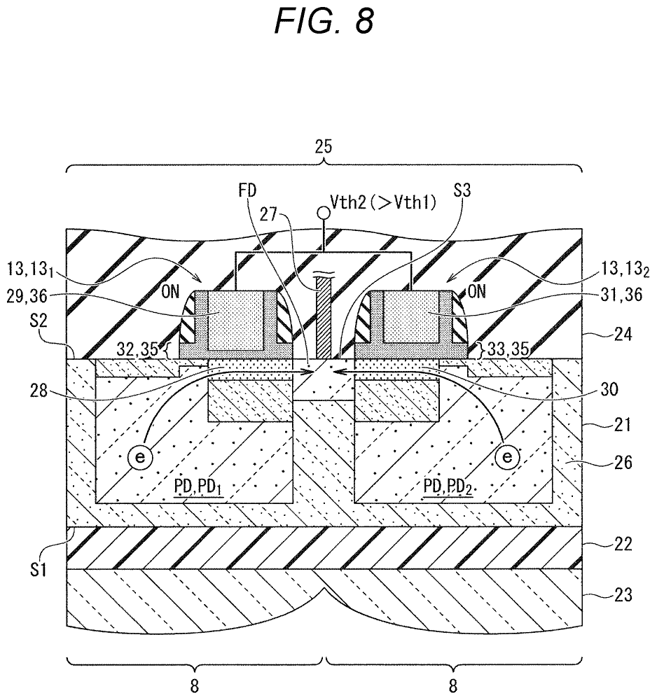

In addition, for example, as illustrated in FIG. 8, if a second voltage Vth2 (high voltage) higher than the first voltage Vth1 is applied to the first gate electrode 29 and the second gate electrode 31 as the transfer pulse φTRF, both the first transfer transistor 13₁ and the second transfer transistor 13₂ are turned on, and a channel is formed in both the first channel formation region 28 and the second channel formation region 30. Then, the charges accumulated in the first photoelectric conversion unit PD₁ and the charges accumulated in the second photoelectric conversion unit PD₂ are simultaneously transferred to the charge accumulation region FD through the formed channel.

The color filters 22 are arranged in a two-dimensional array such that one color filter 22 is arranged for one block 25. As the color filter 22, for example, a filter that transmits light of a predetermined wavelength such as RGB light can be adopted. Thus, the color filter 22 transmits light of a predetermined wavelength and causes the transmitted light to be incident on the photoelectric conversion unit PD.

The microlenses 23 are arranged in a two-dimensional array such that one microlens 23 is arranged for one photoelectric conversion unit PD. The microlenses 23 condense light from a subject, and causes the condensed light to be incident on the photoelectric conversion unit PD via the color filter 22.

The wiring layer 24 includes an interlayer insulating film and a plurality of layers of wirings (not illustrated) stacked via the interlayer insulating film and drives the pixel transistor of each pixel 8 via the plurality of layers of wirings.

In the solid-state imaging device 1 having the above configuration, light is emitted from the back surface S1 side of the semiconductor substrate 21, the emitted light passes through the microlens 23 and the color filter 22, and the transmitted light is photoelectrically converted by the photoelectric conversion unit PD to generate charges (electrons). Then, the generated charges are output as a pixel signal from the vertical signal line 10 in FIG. 1 formed by the wiring of the wiring layer 24.

Furthermore, in a bright place, the solid-state imaging device 1 according to the first embodiment transfers the charges of the first photoelectric conversion unit PD₁ out of the adjacent first photoelectric conversion unit PD₁ and second photoelectric conversion unit PD₂ to the charge accumulation region FD, and executes SDR imaging. In addition, in a dark place, the solid-state imaging device 1 simultaneously transfers the charges of the first photoelectric conversion unit PD₁ and the charges of the second photoelectric conversion unit PD₂ to the charge accumulation region FD, and executes HDR imaging.

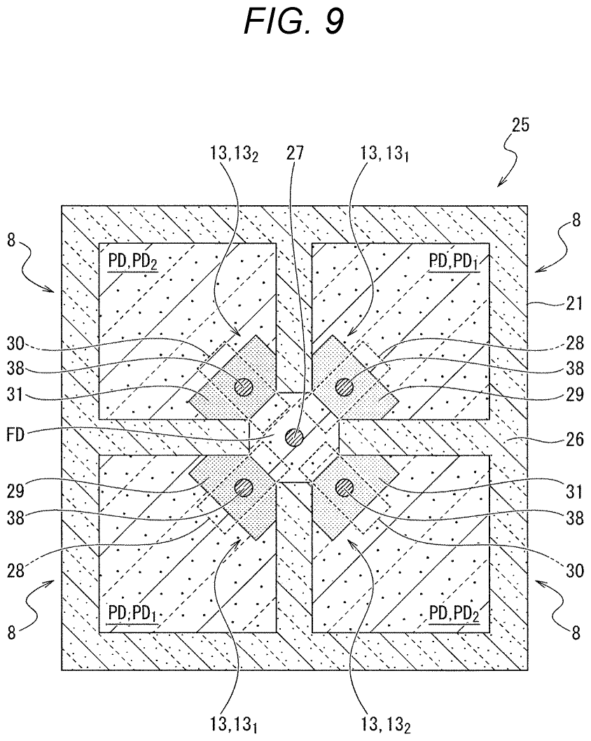

Here, for example, as illustrated in FIG. 9, a case will be considered in which a configuration (configuration of a comparative example) is adopted in which the first gate electrode 29 and the second gate electrode 31 apart from each other are electrically insulated, and the thickness of the first gate insulating film 32 and the thickness of the second gate insulating film 33 are made the same. FIG. 9 is a view illustrating a planar configuration of the solid-state imaging device 1 according to a modification. In a case where such a configuration is adopted, gate electrodes as many as the photoelectric conversion units PD are required in order to perform SDR imaging or HDR imaging, and thus, wirings as many as the photoelectric conversion units PD are also required to supply gate voltages to the gate electrodes. Thus, there is a possibility that the number of wirings increases and a degree of freedom in wiring layout decreases.

On the other hand, in the first embodiment, as illustrated in FIG. 4, the pixel transistors include the first transfer transistor 13₁ having the first gate electrode 29 facing the first channel formation region 28 and the second transfer transistor 13₂ having the second gate electrode 31 facing the second channel formation region 30 and electrically connected to the first gate electrode 29. In a case where the first voltage Vth1 (low voltage) is applied to the first gate electrode 29 and the second gate electrode 31, the channel is formed only in the first channel formation region 28, and in a case where the second voltage Vth2 (>Vth1, high voltage) is applied to the first gate electrode 29 and the second gate electrode 31, the channel is formed in both the first channel formation region 28 and the second channel formation region 30.

With such a configuration, by a voltage being applied to one of the first gate electrode 29 and the second gate electrode 31, a voltage can also be applied to the other. Then, for example, at the time of imaging in a bright place, as illustrated in FIG. 7, by the first voltage Vth1 (low voltage) as the transfer pulse φTRF being applied to the first gate electrode 29 and the second gate electrode 31, only the first transfer transistor 13₁ can be turned on while the second transfer transistor 13₂ is maintained in an off state. Thus, a channel can be formed only in the first channel formation region 28 facing the first gate electrode 29, only the charges (for example, electrons) accumulated in the first photoelectric conversion unit PD₁ can be transferred to the charge accumulation region FD through the formed channel, and SDR imaging can be implemented.

Furthermore, for example, at the time of imaging in a dark place, as illustrated in FIG. 8, by a second voltage Vth2 (high voltage) higher than the first voltage Vth1 as the transfer pulse φTRF being applied to the first gate electrode 29 and the second gate electrode 31, both the first transfer transistor 13₁ and the second transfer transistor 13₂ can be turned on. Thus, a channel can be formed in both the first channel formation region 28 and the second channel formation region 30.

Then, the charges accumulated in the first photoelectric conversion unit PD₁ and the charges accumulated in the second photoelectric conversion unit PD₂ can be simultaneously transferred to the charge accumulation region FD through the formed channel, and HDR imaging can be implemented.

Furthermore, with the above configuration, in the solid-state imaging device 1 according to the first embodiment, the number of wirings (for example, the transfer lines 18 in FIG. 2) that supply the gate voltages to the transfer transistor 13 only requires to be half the number of photoelectric conversion units PD. It is therefore possible to reduce the number of wirings and improve a degree of freedom in wiring layout.

### 2. Second Embodiment

### [2-1 Configuration of Main Part]

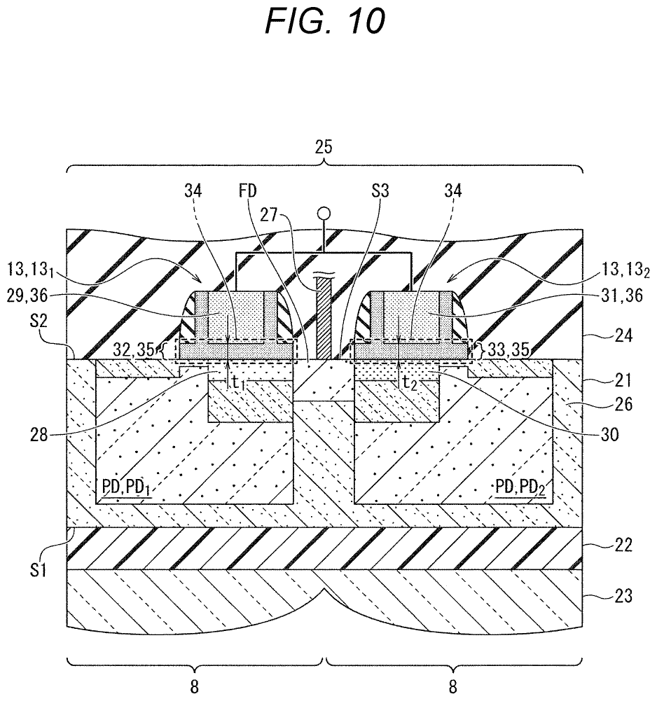

Next, the solid-state imaging device 1 according to a second embodiment of the present disclosure will be described. An overall configuration of the solid-state imaging device 1 of the second embodiment is similar to that in FIG. 1, and thus illustration thereof will be omitted. FIG. 10 is a view corresponding to FIG. 4 of the first embodiment, and is a view illustrating a cross-sectional configuration of the solid-state imaging device 1 of the second embodiment. In FIG. 10, portions corresponding to those in FIG. 4 are denoted by the same reference numerals, and redundant description will be omitted.

The solid-state imaging device 1 according to the second embodiment is different from that of the first embodiment in a structure of the gate insulating film 35 and impurity concentrations in the first channel formation region 28 and the second channel formation region 30. The thickness of each portion of the gate insulating film 35 is constant. In other words, the thickness t₁ of each portion of the first gate insulating film 32 and the thickness t₂ of each portion of the second gate insulating film 33 are the same. The impurity concentration of the first channel formation region 28 is lower than the impurity concentration of the second channel formation region 30. A difference between these impurity concentrations is set such that a difference between a voltage (first voltage Vth1) at which the channel is formed in the first channel formation region 28 and a voltage (second voltage Vth2) at which the channel is formed in the second channel formation region 30 becomes equal to or larger than a predetermined value (for example, 0.5 V). In other words, the impurity concentration of the first channel formation region 28 is made lower than the impurity concentration of the second channel formation region 30 so that the difference between the first voltage Vth1 and the second voltage Vth2 becomes equal to or larger than the predetermined value.

As described above, as a result of a difference in impurity concentration being provided between the first channel formation region 28 and the second channel formation region 30, in the solid-state imaging device 1 according to the second embodiment, for example, by the first voltage Vth1 (low voltage) being applied to the first gate electrode 29 and the second gate electrode 31, only the first transfer transistor 13₁ can be turned on while the second transfer transistor 13₂ is maintained in the off state, as in the first embodiment. Thus, a channel can be formed only in the first channel formation region 28 facing the first gate electrode 29, and only the charges accumulated in the first photoelectric conversion unit PD₁ can be transferred to the charge accumulation region FD through the formed channel.

Furthermore, for example, by the second voltage Vth2 (>Vth1, high voltage) being applied to the first gate electrode 29 and the second gate electrode 31, both the first transfer transistor 13₁ and the second transfer transistor 13₂ can be turned on. Thus, a channel can be formed in both the first channel formation region 28 and the second channel formation region 30. Then, the charges accumulated in the first photoelectric conversion unit PD₁ and the charges accumulated in the second photoelectric conversion unit PD₂ can be simultaneously transferred to the charge accumulation region FD through the formed channel. In addition, with the above configuration, the number of wirings (the transfer lines 18 in FIG. 2) that supply the gate voltages to the transfer transistor 13 only requires to be half the number of photoelectric conversion units PD. It is therefore possible to reduce the number of wirings and improve a degree of freedom in wiring layout.

### [2-2 Modifications]

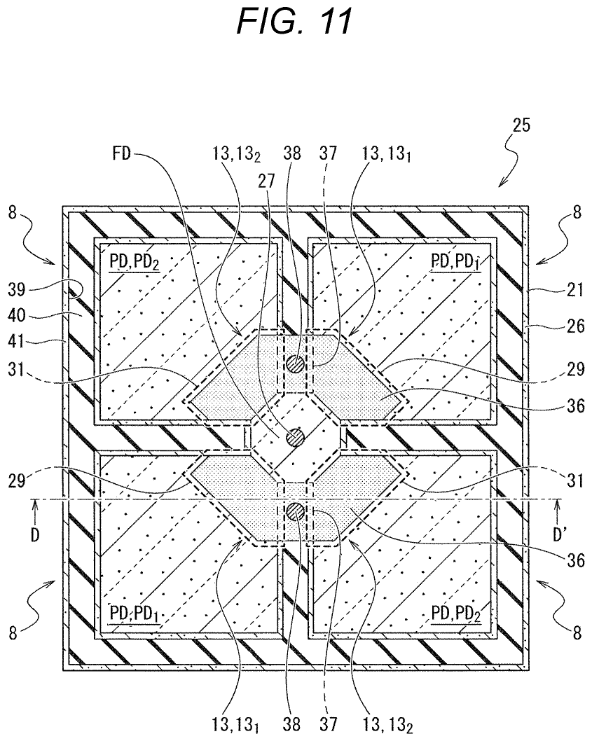

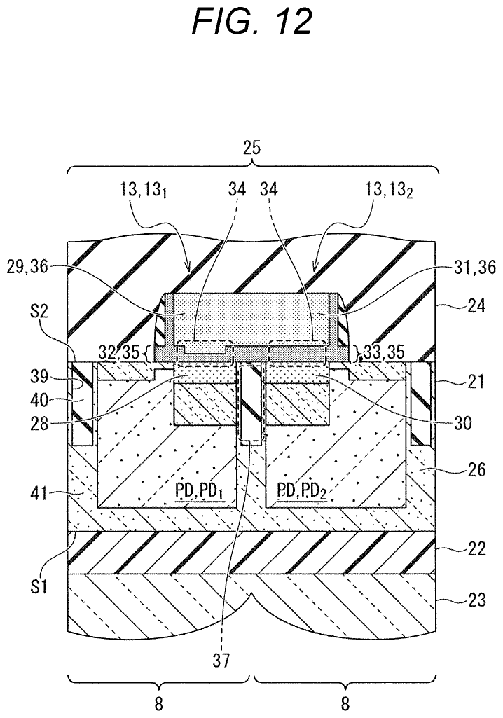

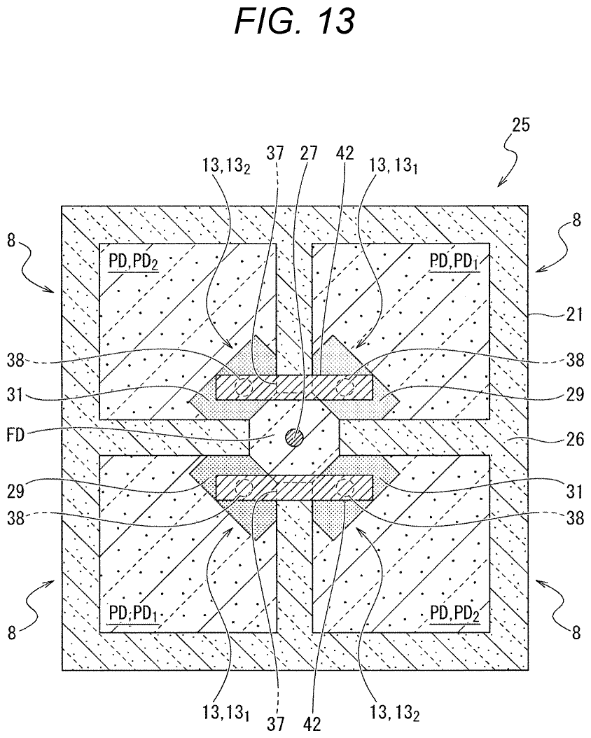

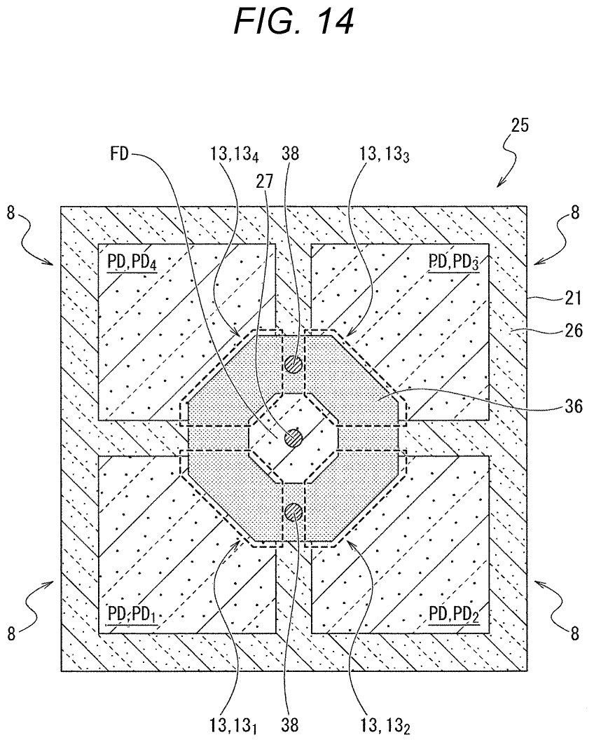

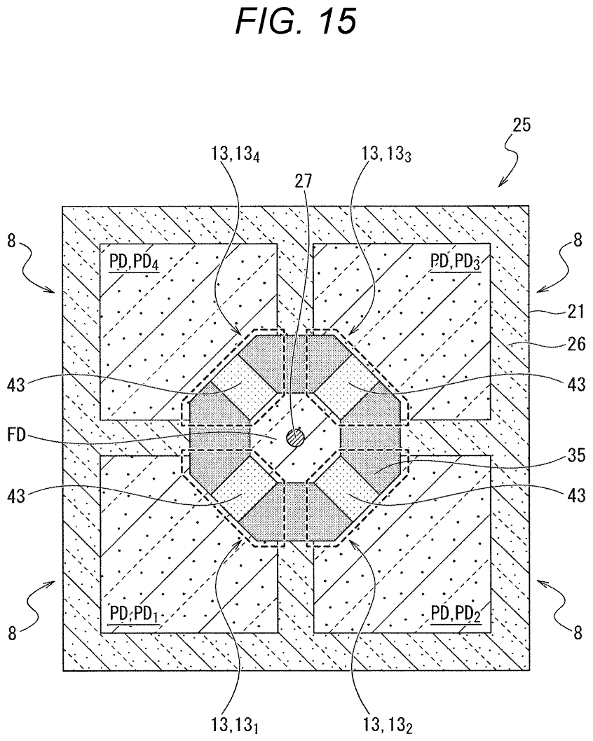

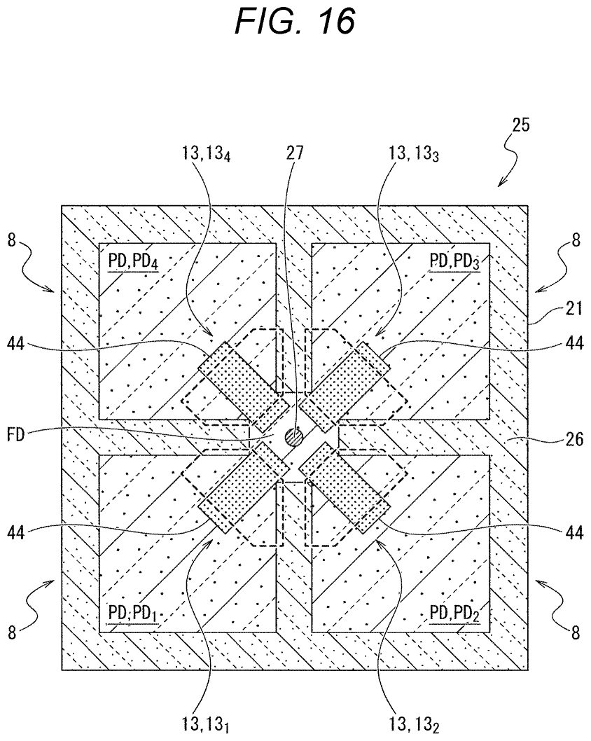

(1) Note that in the second embodiment, the example in which the thickness t₁ of each portion of the first gate insulating film 32 and the thickness t₂ of each portion of the second gate insulating film 33 are the same has been described, but other configurations can be adopted. For example, it is also possible to adopt a configuration in which a difference in impurity concentration is provided in the first channel formation region 28 and the second channel formation region 30 such that the difference between the first voltage Vth1 and the second voltage Vth2 becomes equal to or larger than the predetermined value (for example, 0.5 V), and the thickness t₁ of each portion of the first gate insulating film 32 and the thickness t₂ of each portion of the second gate insulating film 33 are made different.
(2) Furthermore, in the first and second embodiments, the example in which the pixel isolation portion 26 includes a p-type semiconductor region has been described, but other configurations can be adopted. For example, as illustrated in FIGS. 11 and 12, it is also possible to adopt a configuration in which, in the solid-state imaging devices 1 according to the first and second embodiments, the pixel isolation portion 26 includes a trench portion 39 formed at the center of the pixel isolation portion 26 in a width direction and an insulating film 40 embedded in the trench portion 39. The trench portion 39 is a trench portion formed by being dug in a depth direction from the front surface S2 side. FIG. 12 is a view illustrating a cross-sectional configuration of the solid-state imaging device 1 taken along a line D-D′ of FIG. 11. FIG. 12 illustrates an example of a case where a portion of the pixel isolation portion 26 on the back surface S1 side of the semiconductor substrate 21 is constituted only with a p-type semiconductor region (hereinafter, also referred to as “impurity region 41”), and a portion on the front surface S2 side is constituted with an impurity region 41 and an insulating film 40. Here, for example, if a voltage is applied to the gate electrode 36, the voltage is applied to a region (isolation region 37) located between the first photoelectric conversion unit PD₁ and the second photoelectric conversion unit PD₂ in the pixel isolation portion 26. Thus, for example, in a case where the portion on the front surface S2 side of the pixel isolation portion 26 includes only the impurity region 41, a potential barrier of the impurity region 41 of the isolation region 37 decreases, and blooming that causes charge leakage between the first photoelectric conversion unit PD₁ and the second photoelectric conversion unit PD₂ may occur. On the other hand, in the present modification, the portion on the front surface S2 side of the pixel isolation portion 26 includes the impurity region 41 and the insulating film 40, and thus, even if the potential barrier of the impurity region 41 of the isolation region 37 decreases, charge leakage between the first photoelectric conversion unit PD₁ and the second photoelectric conversion unit PD₂ can be suppressed by the insulating film 40, and blooming can be suppressed. FIG. 12 illustrates an example of a case where the present modification is applied to the solid-state imaging device 1 according to the first embodiment.
(3) In the first and second embodiments, the example in which the first gate electrode 29 and the second gate electrode 31 are continuously formed has been described, but the present technology is not limited thereto. For example, as illustrated in FIG. 13, it is also possible to adopt a configuration in which, in the solid-state imaging devices 1 according to the first and second embodiments, the first gate electrode 29 and the second gate electrode 31 are physically divided and formed, and the first gate electrode 29 and the second gate electrode 31 are electrically connected via the wiring 42 of the wiring layer 24. FIG. 13 illustrates an example of a case where each of the first gate electrode 29 and the second gate electrode 31 is connected to the contact 38 and electrically connected to each other via the contact 38 and the wiring 42 of the wiring layer 24. As a result, for example, even if a voltage is applied to the first gate electrode 29 and the second gate electrode 31, it is not necessary to apply a voltage to a region (isolation region 37) located between the first photoelectric conversion unit PD₁ and the second photoelectric conversion unit PD₂in the pixel isolation portion 26. It is therefore possible to prevent decrease in potential barrier of the isolation region 37, suppress charge leakage between the first photoelectric conversion unit PD₁ and the second photoelectric conversion unit PD₂, and suppress blooming.
(4) In addition, in the first and second embodiments, the example has been described in which one gate insulating film 35 and one gate electrode 36 are formed for the first photoelectric conversion unit PD₁ and the second photoelectric conversion unit PD₂ which are a pair of adjacent photoelectric conversion units PD, but other configurations can also be adopted. For example, as illustrated in FIGS. 14, 15, and 16, it is also possible to adopt a configuration in which, in the solid-state imaging device 1 according to the first and second embodiments, one gate insulating film 35 and one gate electrode 36 are formed for four photoelectric conversion units (hereinafter, also referred to as the “first photoelectric conversion unit PD₁”, the “second photoelectric conversion unit PD₂”, a “third photoelectric conversion unit PD₃”, and a “fourth photoelectric conversion unit PD₄”) constituting one block 25. In this case, each of the gate insulating film 35 and the gate electrode 36 is formed in an annular band shape along the outer periphery of the exposed surface S3 of the charge accumulation region FD so as to continuously cover the front surfaces S2 of the first photoelectric conversion unit PD₁, the second photoelectric conversion unit PD₂, the third photoelectric conversion unit PD₃, and the fourth photoelectric conversion unit PD₄. FIG. 15 is a view illustrating a case where the present modification is applied to the solid-state imaging device 1 according to the first embodiment. Furthermore, FIG. 16 is a view illustrating a case where the present modification is applied to the solid-state imaging device 1 according to the second embodiment.

Here, in a case where the present modification is applied to the solid-state imaging device 1 according to the first embodiment, as illustrated in FIG. 15, it is assumed that the thickness of the gate insulating film 35 of the transfer transistor (hereinafter, also referred to as the “first transfer transistor 13₁”) corresponding to the first photoelectric conversion unit PD₁<the thickness of the gate insulating film 35 of the transfer transistor (hereinafter, also referred to as the “second transfer transistor 13₂”) corresponding to the second photoelectric conversion unit PD₂<the thickness of the gate insulating film 35 of the transfer transistor (hereinafter, also referred to as the “third transfer transistor 13₃”) corresponding to the third photoelectric conversion unit PD₃<the thickness of the gate insulating film 35 of the transfer transistor (hereinafter, also referred to as the “fourth transfer transistor 13₄”) corresponding to the fourth photoelectric conversion unit PD₄. FIG. 15 illustrates an example of a case where the above order is achieved in the band-shaped region 43 of the gate insulating film 35 extending from each of the first photoelectric conversion unit PD₁ side, the second photoelectric conversion unit PD₂ side, the third photoelectric conversion unit PD₃ side, and the fourth photoelectric conversion unit PD₄ side to the charge accumulation region FD side.

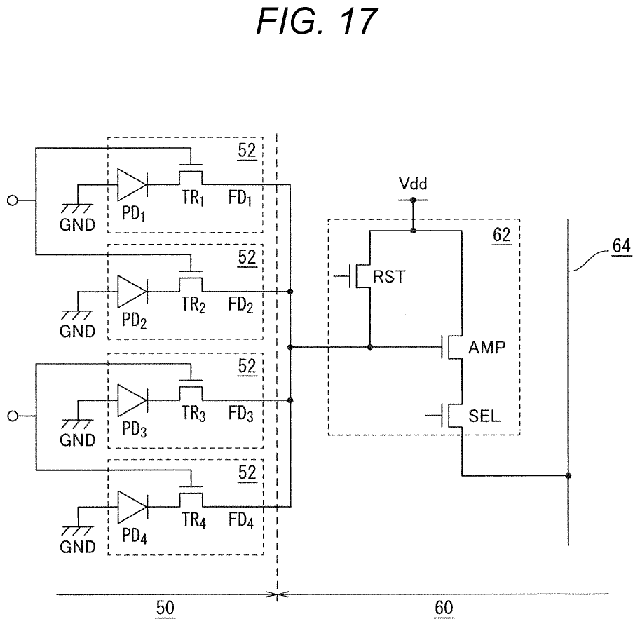

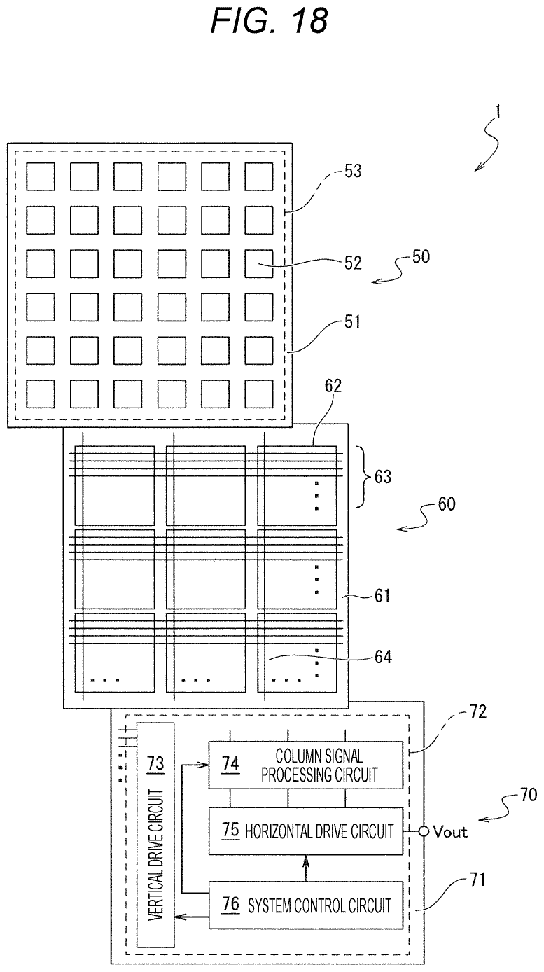

Furthermore, in a case where the present modification is applied to the solid-state imaging device 1 according to the second embodiment, as illustrated in FIG. 16, it is assumed that the impurity concentration of the channel formation region 44 of the first transfer transistor 13₁<the impurity concentration of the channel formation region 44 of the second transfer transistor 13₂<the impurity concentration of the channel formation region 44 of the third transfer transistor 13₃<the impurity concentration of the channel formation region 44 of the fourth transfer transistor 13₄. FIG. 16 illustrates a planar configuration of the solid-state imaging device 1 in a case where the gate insulating film 35 and the gate electrode 36 are omitted so that the channel formation region 44 becomes clear.
(5) In addition, in the first and second embodiments, the example in which the charge accumulation region FD is shared by 2×2 photoelectric conversion units PD has been described, but other configurations can be adopted. For example, as illustrated in FIG. 17, it is also possible to adopt a configuration in which, in the solid-state imaging device 1 according to the first and second embodiments, the floating diffusion FD (corresponding to the “charge accumulation region FD” in FIG. 2) is formed for each sensor pixel 52 (corresponding to the “pixel 8” in FIG. 2), and 2×2 floating diffusions FD are electrically connected. FIG. 17 illustrates an example of the sensor pixel 52 and the readout circuit 62. In this case, for example, as illustrated in FIG. 18, the solid-state imaging device 1 may include three substrates (a first substrate 50, a second substrate 60, a third substrate 70). FIG. 18 is a view illustrating an example of a schematic configuration of the solid-state imaging device 1 according to the present modification. The solid-state imaging device 1 has a three-dimensional structure in which the first substrate 50, the second substrate 60, and the third substrate 70 are bonded together. The first substrate 50, the second substrate 60, and the third substrate 70 are stacked in this order.

The first substrate 50 includes a plurality of sensor pixels 52 (corresponding to the “pixels 8” in FIG. 1) that performs photoelectric conversion on the semiconductor substrate 51 (corresponding to the “semiconductor substrate 21” in FIG. 1). The plurality of sensor pixels 52 is provided in a matrix in the pixel region 53 (corresponding to the “pixel region 2” in FIG. 1) of the first substrate 50. The second substrate 60 includes, on the semiconductor substrate 61, readout circuits 62 that read out pixel signals based on charges output from the sensor pixels 52, each of which is provided for each of four sensor pixels 52. Further, the second substrate 60 includes a plurality of pixel drive lines 63 (corresponding to the “pixel drive wirings 9” in FIG. 1) extending in a row direction and a plurality of vertical signal lines 64 (corresponding to the “vertical signal lines 10” in FIG. 1) extending in a column direction. Still further, the third substrate 70 includes a logic circuit 72 that processes a pixel signal, on a semiconductor substrate 71. The logic circuit 72 includes, for example, a vertical drive circuit 73 (corresponding to the “vertical drive circuit 3” in FIG. 1), a column signal processing circuit 74 (corresponding to the “column signal processing circuit 4” in FIG. 1), a horizontal drive circuit 75 (corresponding to the “horizontal drive circuit 5” in FIG. 1), and a system control circuit 76 (corresponding to the “control circuit 7” in FIG. 1). The logic circuit 72 (specifically, the horizontal drive circuit 75) outputs an output voltage Vout for each of the sensor pixels 52 to the outside. In the logic circuit 72, a low-resistance region, which includes a silicide formed by using a self aligned silicide (salicide) process such as CoSi₂ or NiSi, may be formed on, for example, a front surface of an impurity diffusion region that is in contact with a source electrode and a drain electrode.

The vertical drive circuit 73 sequentially selects the plurality of sensor pixels 52 row by row, for example. The column signal processing circuit 74 performs, for example, correlated double sampling (CDS) processing on the pixel signal output from each of the sensor pixels 52 in the row selected by the vertical drive circuit 73. The column signal processing circuit 74 extracts a signal level of the pixel signal by performing CDS processing, for example, and holds pixel data corresponding to an amount of light received by each of the sensor pixels 52. Further, the horizontal drive circuit 75 sequentially outputs the pixel data held in the column signal processing circuit 74 to the outside, for example. Still further, the system control circuit 76 controls driving of the respective blocks (the vertical drive circuit 73, the column signal processing circuit 74, the horizontal drive circuit 75) in the logic circuit 72, for example.

Hereinafter, as illustrated in FIG. 17, a case where four sensor pixels 52 (floating diffusions FD) share one readout circuit 62 will be described. Here, “sharing” means that outputs of the four sensor pixels 52 are input to the common readout circuit 62. Further, each sensor pixel 52 has a common component. In FIG. 17, identification numbers (1, 2, 3, 4) are added to ends of the reference numerals of the components of the sensor pixels 52 in order to distinguish the components of the sensor pixels 52 from each other. In a case where it is necessary to distinguish the components of the sensor pixels 52 from each other, the identification numbers are attached to ends of the reference numerals of the components of the sensor pixels 52, but in a case where it is not necessary to distinguish the components of the sensor pixels 52 from each other, the identification numbers at the ends of the reference numerals of the components of the sensor pixels 52 are omitted.

Each sensor pixel 52 includes, for example, a photodiode PD (corresponding to the “photoelectric conversion unit PD” in FIG. 2), a transfer transistor TR (corresponding to the “transfer transistor 13” in FIG. 2) electrically connected to the photodiode PD, and a floating diffusion FD (corresponding to the “charge accumulation region FD” in FIG. 2) that temporarily holds the charges output from the photodiode PD via the transfer transistor TR. The photodiode PD generates charges according to the amount of received light by performing photoelectric conversion. A cathode of the photodiode PD is electrically connected to a source of the transfer transistor TR, and an anode of the photodiode PD is electrically connected to a reference potential line (for example, ground). Further, a drain of the transfer transistor TR is electrically connected to the floating diffusion FD, and a gate of the transfer transistor TR is electrically connected to the pixel drive line 63 (see FIG. 18). As the transfer transistor TR, for example, a CMOS transistor can be adopted.

Here, the present technology is applied to the transfer transistor 13₁ and the transfer transistor 13₂, and the transfer transistor 13₃ and the transfer transistor 13₄. For example, the gate electrode of the transfer transistor 13₁ is electrically connected to the gate electrode of the transfer transistor 13₂, and the gate electrode of the transfer transistor 13₃ is electrically connected to the gate electrode of the transfer transistor 13₄. In addition, the gate electrodes, the gate insulating films, and the channel formation regions of the transfer transistor 13₁ and the transfer transistor 13₃ have configurations similar to those of the “first gate electrode 29”, the “first gate insulating film 32”, and the “first channel formation region 28” of the first or second embodiment. In addition, the gate electrodes, the gate insulating films, and the channel formation regions of the transfer transistor 13₂ and the transfer transistor 13₃ have configurations similar to those of the “second gate electrode 31”, the “second gate insulating film 33”, and the “second channel formation region 30” of the first or second embodiment. In other words, it is assumed that the thickness of the gate insulating film of the transfer transistor 13₁<the thickness of the gate insulating film of the transfer transistor 13₂, the thickness of the gate insulating film of the transfer transistor 13₃<the thickness of the gate insulating film of the transfer transistor 13₄. Alternatively, it is assumed that the impurity concentration in the channel formation region of the transfer transistor 13₁<the impurity concentration in the channel formation region of the transfer transistor 13₂, the impurity concentration in the channel formation region of the transfer transistor 13₃<the impurity concentration in the channel formation region of the transfer transistor 13₄.

The floating diffusions FD of the sensor pixels 52 sharing one readout circuit 62 are electrically connected to each other and are electrically connected to an input end of the common readout circuit 62. The readout circuit 62 includes, for example, a reset transistor RST (corresponding to the “reset transistor 14” in FIG. 2), a selection transistor SEL (corresponding to the “selection transistor 16” in FIG. 2), and an amplification transistor AMP (corresponding to the “amplification transistor 15” in FIG. 2). Note that the selection transistor SEL may be omitted. In the readout circuit 62, a source of the reset transistor RST (the input end of the readout circuit 62) is electrically connected to the floating diffusion FD, and a drain of the reset transistor RST is electrically connected to the power supply line Vdd and a drain of the amplification transistor AMP. A gate of the reset transistor RST is electrically connected to the pixel drive line 63 (see FIG. 18). Further, a source of the amplification transistor AMP is electrically connected to a drain of the selection transistor SEL, and a gate of the amplification transistor AMP is electrically connected to the source of the reset transistor RST. A source of the selection transistor SEL (the output end of the readout circuit 62) is electrically connected to the vertical signal line 64, and a gate of the selection transistor SEL is electrically connected to the pixel drive line 63 (see FIG. 18).

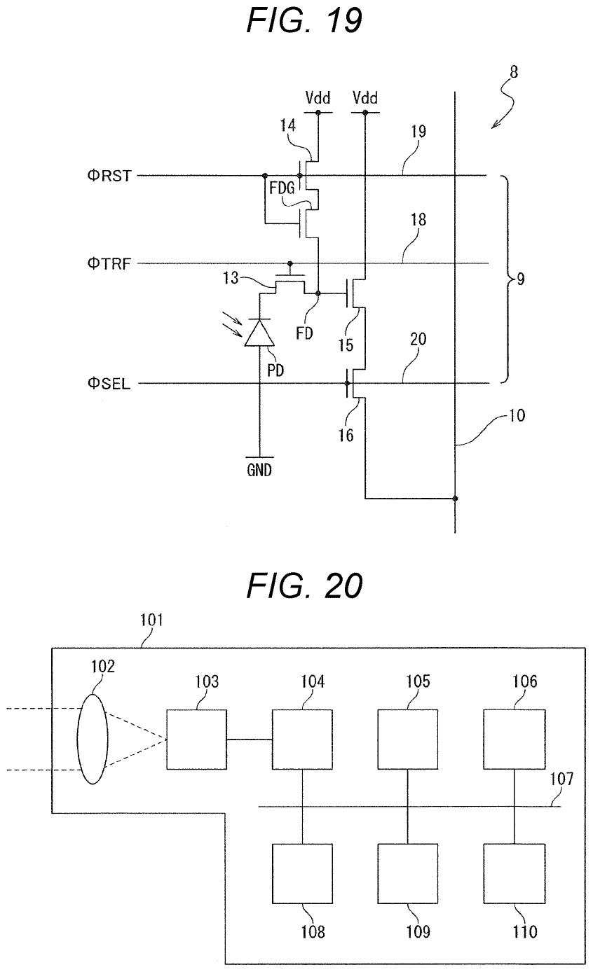

The transfer transistor TR transfers charges of the photodiode PD to the floating diffusion FD if the transfer transistor TR is turned on. The reset transistor RST resets a potential of the floating diffusion FD to a predetermined potential. The reset transistor RST resets the potential of the floating diffusion FD to a potential of the power supply line Vdd when the reset transistor RST is turned on. The selection transistor SEL controls an output timing of the pixel signal from the readout circuit 62. The amplification transistor AMP generates a signal of a voltage corresponding to a level of the charges held in the floating diffusion FD as the pixel signal. The amplification transistor AMP constitutes a source follower type amplifier and outputs the pixel signal of the voltage corresponding to the level of the charges generated by the photodiode PD. If the selection transistor SEL is turned on, the amplification transistor AMP amplifies the potential of the floating diffusion FD, and outputs a voltage corresponding to the potential to the column signal processing circuit 74 via the vertical signal line 64. The reset transistor RST, the amplification transistor AMP, and the selection transistor SEL are, for example, CMOS transistors.
(6) Furthermore, in the first and second embodiments, the example has been described in which the present technology is applied to the transfer transistor 13 of the first photoelectric conversion unit PD₁ and the transfer transistor 13 of the second photoelectric conversion unit PD₂, but other configurations can be adopted. For example, as illustrated in FIG. 19, it is also possible to adopt a configuration in which, in the solid-state imaging device 1 according to the first and second embodiments, a switching transistor FDG for switching capacitance of the charge accumulation region FD is formed between the charge accumulation region FD and the reset transistor 14, and the present technology (technology disclosed in the first and second embodiments, and the like) is applied to the reset transistor 14 and the switching transistor FDG. The switching transistor FDG is a pixel transistor that adds gate capacitance of the switching transistor FDG to the charge accumulation region FD and switches the capacitance of the charge accumulation region FD if the switching transistor FDG is turned on.

In this case, the gate electrode, the gate insulating film, and the channel formation region of the switching transistor FDG have configurations similar to those of the “first gate electrode 29”, the “first gate insulating film 32”, and the “first channel formation region 28” of the first or second embodiment, and the gate electrode, the gate insulating film, and the channel formation region of the reset transistor 14 have configurations similar to those of the “second gate electrode 31”, the “second gate insulating film 33”, and the “second channel formation region 30” of the first or second embodiment. With the above configurations, for example, by the first voltage Vth1 (low voltage) being applied to the first gate electrode 29 of the switching transistor FDG and the second gate electrode 31 of the reset transistor 14, a channel can be formed only in the first channel formation region 28. Then, the gate capacitance of the switching transistor FDG can be added to the capacitance of the charge accumulation region FD through the formed channel. Further, for example, by the second voltage Vth2 (high voltage) being applied to the first gate electrode 29 and the second gate electrode 31, a channel can be formed in both the first channel formation region 28 and the second channel formation region 30. Then, the charges accumulated in the charge accumulation region FD and the gate capacitance of the switching transistor FDG and the charges accumulated in the second photoelectric conversion unit PD₂ are discarded through the formed channel, so that the charge accumulation region FD and the gate capacitance of the switching transistor FDG can be reset.
(7) Furthermore, the present technology can be applied to any photodetection device including not only the above-described solid-state imaging device 1 as an image sensor but also a ranging sensor, which is also referred to as a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. As a light receiving pixel structure of the ranging sensor, the structure of the pixel 8 described above may be employed.

Furthermore, the present technology can be also applied to general semiconductor devices in addition to the photodetection device.

### 3. Third Embodiment

The technology (present technology) according to the present disclosure may be applied to various kinds of electronic equipment. For example, the present technology can be applied to various kinds of electronic equipment such as an imaging system such as, for example, a digital still camera or a digital video camera, a mobile phone having an imaging function, or another equipment having an imaging function.

FIG. 20 is a block diagram illustrating a configuration example of the electronic equipment. As illustrated in FIG. 20, electronic equipment 101 includes an optical system 102, a photodetection device 103 (the solid-state imaging device 1 of any of the above-described configuration examples), and a digital signal processor (DSP) 104, is configured by a DSP 104, a display device 105, an operation system 106, a memory 108, a recording device 109, and a power supply system 110 being connected via a bus 107, and can capture a still image and a moving image.

The optical system 102 includes one or a plurality of lenses, guides image light (incident light) from a subject to the photodetection device 103, and forms an image on a light receiving surface (sensor unit) of the photodetection device 103.

As the photodetection device 103, the solid-state imaging device 1 described above is applied. In the photodetection device 103, electrons are accumulated for a certain period according to an image formed on the light receiving surface via the optical system 102. Then, a signal corresponding to the electrons accumulated in the photodetection device 103 is supplied to the DSP 104.

The DSP 104 performs various types of signal processing on the signal supplied from the photodetection device 103 to acquire an image, and temporarily stores data of the acquired image in the memory 108. The data of the image stored in the memory 108 is recorded in the recording device 109 or supplied to the display device 105 to display the image. In addition, the operation system 106 receives various kinds of operation from the user and supplies an operation signal to each block (for example, the DSP 104) of the electronic equipment 101. In addition, the power supply system 110 supplies power necessary for driving each block of the electronic equipment 101.

In the electronic equipment 101 configured as described above, a degree of freedom in wiring layout can be improved by applying the solid-state imaging device 1 as described above as the photodetection device 103.

### 4. Example of Application to Mobile Body

The technology according to the present disclosure (present technology) can be also applied to various kinds of products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

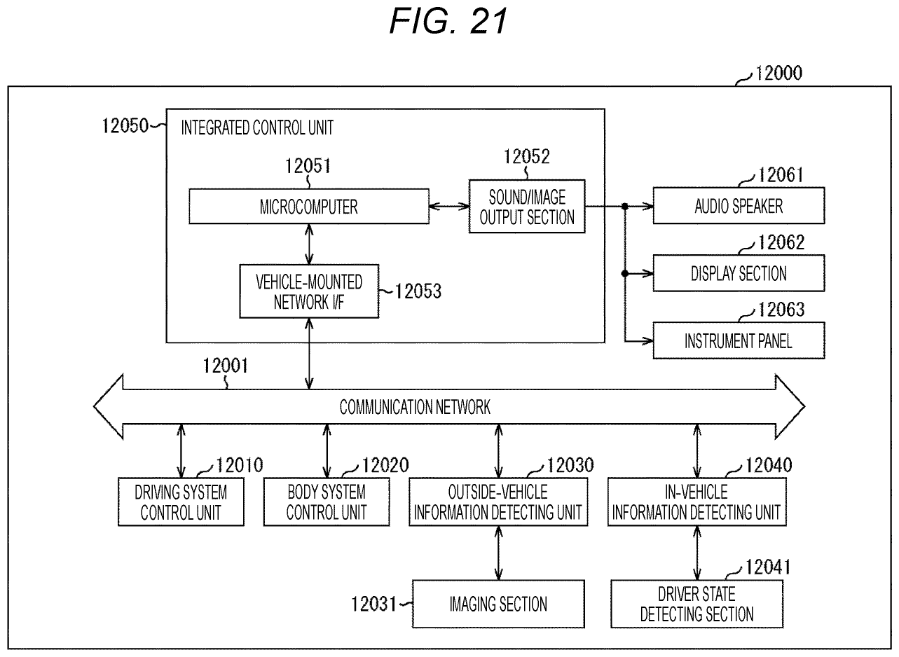

FIG. 21 is a block diagram illustrating an example of a schematic configuration of a vehicle control system that is an example of a mobile body control system to which the technology according to the present disclosure can be applied.

The vehicle control system 12000 includes a plurality of electronic control units connected to each other via a communication network 12001. In the example illustrated in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

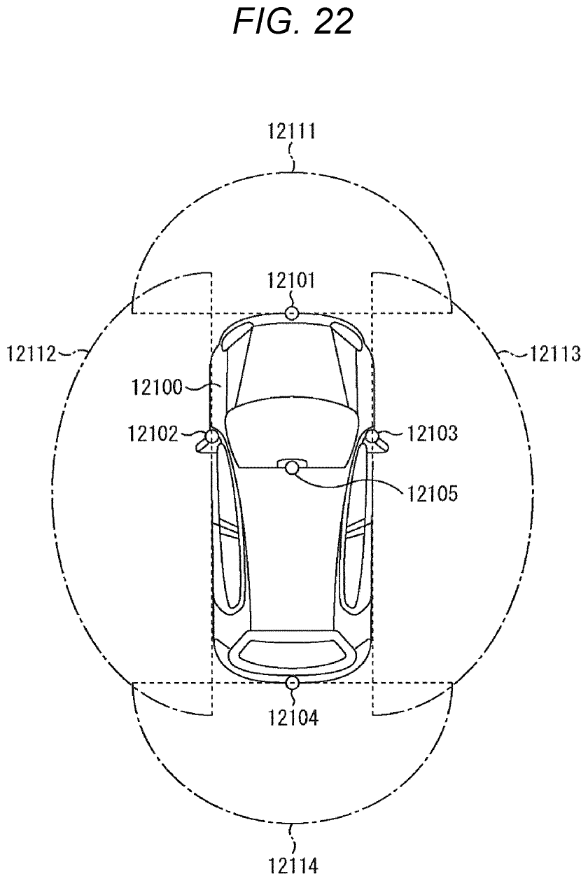

FIG. 22 is a view illustrating an example of a position where the imaging section 12031 is provided.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 22 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology of the present disclosure can be applied to the imaging section 12031 among the components described above.

Specifically, the solid-state imaging device 1 according to the first embodiment (see FIGS. 3 to 6) and the solid-state imaging device 1 according to the second embodiment (see FIG. 10) can be applied to the imaging section 12031. By the technology according to the present disclosure being applied to the imaging section 12031, a degree of freedom in wiring layout of the imaging section 12031 can be improved, so that the manufacturing cost of the imaging section 12031 can be reduced.

### 5. Example of Application to Endoscopic Surgery System

The technology according to the present disclosure (present technology) can be also applied to various kinds of products. For example, the technology according to the present disclosure may be applied to an endoscopic surgery system.

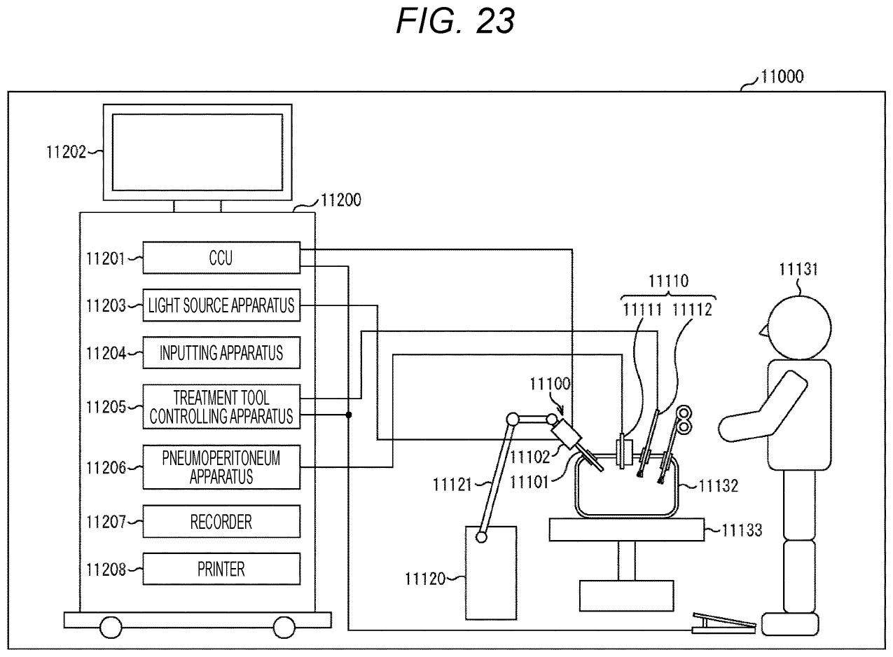

FIG. 23 is a view illustrating an example of a schematic configuration of an endoscopic surgery system to which the technology according to the present disclosure (present technology) can be applied.

FIG. 23 illustrates a state in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

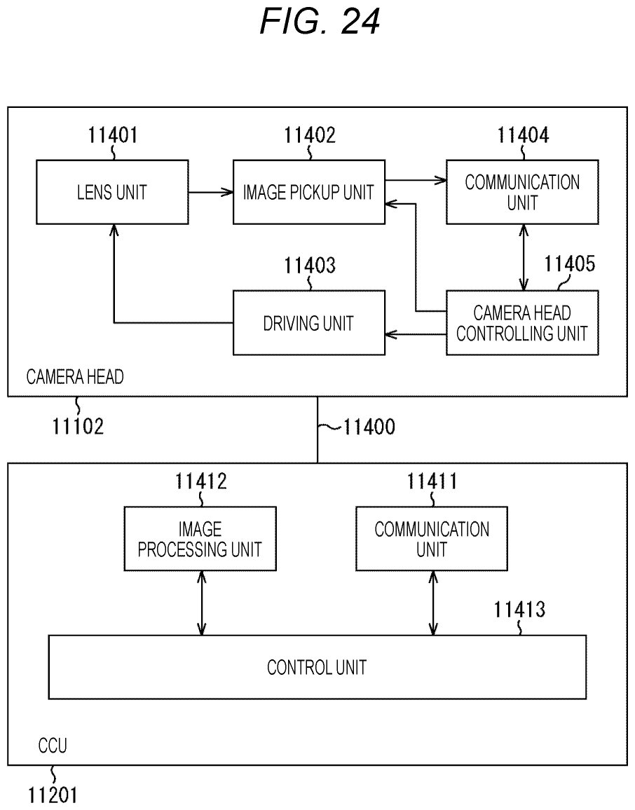

FIG. 24 is a block diagram illustrating an example of a functional configuration of the camera head 11102 and the CCU 11201 illustrated in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The conrol unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged.

Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the endoscope 11100, the image pickup unit 11402 of the camera head 11102, and the like, among the above-described components. Specifically, the solid-state imaging device 1 according to the first embodiment (see FIGS. 3 to 6) and the solid-state imaging device 1 according to the second embodiment (see FIG. 10) can be applied to the image pickup unit 11402. By the technology according to the present disclosure being applied to the image pickup unit 11402, a degree of freedom in wiring layout of the image pickup unit 11402 can be improved, so that the manufacturing cost of the image pickup unit 11402 can be reduced.

Note that an endoscopic surgery system has been described as an example herein, but the technology according to the present disclosure may be applied to a microscopic surgery system, and the like, for example.

Note that, the present technology may also have the following configurations.

(1)

A photodetection device including
a semiconductor substrate,
a plurality of photoelectric conversion units formed in a two-dimensional array on the semiconductor substrate, and
a plurality of pixel transistors, in which
a plurality of the pixel transistors includes a first transistor having a first gate electrode facing a first channel formation region, and a second transistor having a second gate electrode facing a second channel formation region and electrically connected to the first gate electrode, in a case where a first voltage is applied to the first gate electrode and the second gate electrode, a channel is formed only in the first channel formation region, and in a case where a second voltage higher than the first voltage is applied to the first gate electrode and the second gate electrode, a channel is formed in both the first channel formation region and the second channel formation region.
   (2)

The photodetection device according to (1), in which
the first gate electrode faces the first channel formation region via a first gate insulating film,
the second gate electrode faces the second channel formation region via a second gate insulating film, and
a thickness of at least a portion of the first gate insulating film is smaller than a thickness of each portion of the second gate insulating film such that a difference between the first voltage and the second voltage is equal to or larger than a predetermined value.
   (3)

The photodetection device according to (2), further including a charge accumulation region formed on the semiconductor substrate apart from the photoelectric conversion units and shared by two or more of the photoelectric conversion units, in which
the two or more photoelectric conversion units include a first photoelectric conversion unit and a second photoelectric conversion unit adjacent to each other,
the first transistor is a first transfer transistor that transfers charges generated by the first photoelectric conversion unit to the charge accumulation region,
in the first transfer transistor,
the first channel formation region is formed in a region between the first photoelectric conversion unit and the charge accumulation region of the semiconductor substrate on a first surface side that is a surface opposite to a light receiving surface of the semiconductor substrate,
the first gate electrode is formed on the first surface of the semiconductor substrate via the first gate insulating film so as to face the first channel formation region,
the second transistor is a second transfer transistor that transfers charges generated by the second photoelectric conversion unit to the charge accumulation region,
in the second transfer transistor,
the second channel formation region is formed in a region between the second photoelectric conversion unit and the charge accumulation region of the semiconductor substrate on the first surface side of the semiconductor substrate,
the second gate electrode is formed on the first surface of the semiconductor substrate via the second gate insulating film so as to face the second channel formation region, and
further, a thickness of a band-shaped region of the first gate insulating film extending from the first photoelectric conversion unit side to the charge accumulation region side is smaller than a thickness of each portion of the second gate insulating film in a case of being viewed from a thickness direction of the semiconductor substrate.
   (4)

The photodetection device according to (3), in which
thicknesses of remaining regions of the first gate insulating film located on one side and another side sandwiching the band-shaped region are larger than the thickness of the band-shaped region.
   (5)

The photodetection device according to (3) or (4), in which
the first gate electrode and the second gate electrode are continuous.
   (6)

The photodetection device according to (5), further including a pixel isolation portion formed in a region between the photoelectric conversion units adjacent to each other in the semiconductor substrate, in which
the pixel isolation portion includes a p-type semiconductor region,
the charge accumulation region is formed in a region located at a center of a block constituted by 2×2 photoelectric conversion units in the pixel isolation portion and is shared by the 2×2 photoelectric conversion units in a case of being viewed from the thickness direction of the semiconductor substrate,
the first photoelectric conversion unit and the second photoelectric conversion unit are a pair of adjacent photoelectric conversion units included in the 2×2 photoelectric conversion units, and
each of the first gate insulating film and the second gate insulating film, and the first gate electrode and the second gate electrode is continuously formed across a region located between the first photoelectric conversion unit and the second photoelectric conversion unit in the pixel isolation portion in a case of being viewed from the thickness direction of the semiconductor substrate.
   (7)

The photodetection device according to (6), further including a trench portion formed at a center in a width direction of the pixel isolation portion, and an insulating film embedded in the trench portion.

(8)

The photodetection device according to any one of (2) to (4), further including a wiring layer arranged on a first surface opposite to a light receiving surface of the semiconductor substrate, in which the first gate electrode and the second gate electrode are electrically connected via a wiring of the wiring layer.

(9)

The photodetection device according to any one of (1) to (8), in which
an impurity concentration in the first channel formation region is lower than an impurity concentration in the second channel formation region such that a difference between the first voltage and the second voltage is equal to or larger than a predetermined value.
   (10)

The photodetection device according to (9), further including a charge accumulation region formed on the semiconductor substrate apart from the photoelectric conversion units and shared by two or more of the photoelectric conversion units, in which
the two or more photoelectric conversion units include a first photoelectric conversion unit and a second photoelectric conversion unit adjacent to each other,
the first transistor is a first transfer transistor that transfers charges generated by the first photoelectric conversion unit to the charge accumulation region,
in the first transfer transistor,
the first channel formation region is formed in a region between the first photoelectric conversion unit and the charge accumulation region of the semiconductor substrate on a first surface side that is a surface opposite to a light receiving surface of the semiconductor substrate,
the first gate electrode is formed on the first surface of the semiconductor substrate via a first gate insulating film so as to face the first channel formation region,
the second transistor is a second transfer transistor that transfers charges generated by the second photoelectric conversion unit to the charge accumulation region,
in the second transfer transistor,
the second channel formation region is formed in a region between the second photoelectric conversion unit of the semiconductor substrate and the charge accumulation region on the first surface side of the semiconductor substrate, and
the second gate electrode is formed on the first surface of the semiconductor substrate via a second gate insulating film so as to face the second channel formation region.
   (11)

The photodetection device according to (10), in which
the first gate electrode and the second gate electrode are continuous.
   (12)

The photodetection device according to (11), further including a pixel isolation portion formed in a region between the photoelectric conversion units adjacent to each other in the semiconductor substrate, in which
the pixel isolation portion includes a p-type semiconductor region,
the charge accumulation region is formed in a region located at a center of a block constituted by 2×2 photoelectric conversion units in the pixel isolation portion and is shared by the 2×2 photoelectric conversion units in a case of being viewed from a thickness direction of the semiconductor substrate,
the first photoelectric conversion unit and the second photoelectric conversion unit are a pair of adjacent photoelectric conversion units included in the 2×2 photoelectric conversion units, and
each of the first gate insulating film and the second gate insulating film, and the first gate electrode and the second gate electrode is continuously formed across a region located between the first photoelectric conversion unit and the second photoelectric conversion unit in the pixel isolation portion in a case of being viewed from the thickness direction of the semiconductor substrate.
   (13)

The photodetection device according to (12), further including a trench portion formed at a center in a width direction of the pixel isolation portion, and an insulating film embedded in the trench portion.

(14)

The photodetection device according to (9) or (10), further including a wiring layer arranged on a first surface opposite to a light receiving surface of the semiconductor substrate, in which
the first gate electrode and the second gate electrode are electrically connected via a wiring of the wiring layer.
   (15)

Electronic equipment including a photodetection device that includes a semiconductor substrate, a plurality of photoelectric conversion units formed in a two-dimensional array on the semiconductor substrate, and a plurality of pixel transistors, in which
a plurality of the pixel transistors includes a first transistor having a first gate electrode facing a first channel formation region, and a second transistor having a second gate electrode facing a second channel formation region and electrically connected to the first gate electrode, in a case where a first voltage is applied to the first gate electrode and the second gate electrode, a channel is formed only in the first channel formation region, and, in a case where a second voltage higher than the first voltage is applied to the first gate electrode and the second gate electrode, a channel is formed in both the first channel formation region and the second channel formation region.
   (16)

A semiconductor device including
a first transistor having a first gate electrode facing a first channel formation region, and
a second transistor having a second gate electrode facing a second channel formation region and electrically connected to the first gate electrode, in which
in a case where a first voltage is applied to the first gate electrode and the second gate electrode, a channel is formed only in the first channel formation region, and, in a case where a second voltage higher than the first voltage is applied to the first gate electrode and the second gate electrode a channel is formed in both the first gate electrode and the second channel formation region.

### REFERENCE SIGNS LIST

1 Solid-state imaging device
2 Pixel region
3 Vertical drive circuit
4 Column signal processing circuit
5 Horizontal drive circuit
6 Output circuit
7 Control circuit
8 Pixel
9 Pixel drive wiring
10 Vertical signal line
11 Horizontal signal line
13 Transfer transistor
13₁ First transfer transistor
13₂ Second transfer transistor
13₃ Third transfer transistor
13₄ Fourth transfer transistor
14 Reset transistor
15 Amplification transistor
16 Selection transistor
18 Transfer line
19 Reset line
20 Selection line
21 Semiconductor substrate
22 Color filter
23 Microlens
24 Wiring layer
25 Block
26 Pixel isolation portion
27 Contact
28 First channel formation region
29 First gate electrode
30 Second channel formation region
31 Second gate electrode
32 First gate insulating film
33 Second gate insulating film
34 Band-shaped region
35 Gate insulating film
36 Gate electrode
37 Isolation region
38 Contact
39 Trench portion
40 Insulating film
41 Impurity region
42 Wiring
43 Band-shaped region
44 Channel formation region

1. A photodetection device comprising:
a semiconductor substrate;
a plurality of photoelectric conversion units formed in a two-dimensional array on the semiconductor substrate; and
a plurality of pixel transistors, wherein
a plurality of the pixel transistors includes a first transistor having a first gate electrode facing a first channel formation region, and a second transistor having a second gate electrode facing a second channel formation region and electrically connected to the first gate electrode, in a case where a first voltage is applied to the first gate electrode and the second gate electrode, a channel is formed only in the first channel formation region, and in a case where a second voltage higher than the first voltage is applied to the first gate electrode and the second gate electrode, a channel is formed in both the first channel formation region and the second channel formation region.

2. The photodetection device according to claim 1, wherein
the first gate electrode faces the first channel formation region via a first gate insulating film,
the second gate electrode faces the second channel formation region via a second gate insulating film, and
a thickness of at least a portion of the first gate insulating film is smaller than a thickness of each portion of the second gate insulating film such that a difference between the first voltage and the second voltage is equal to or larger than a predetermined value.

3. The photodetection device according to claim 2, further comprising a charge accumulation region formed on the semiconductor substrate apart from the photoelectric conversion units and shared by two or more of the photoelectric conversion units, wherein
the two or more photoelectric conversion units include a first photoelectric conversion unit and a second photoelectric conversion unit adjacent to each other,
the first transistor is a first transfer transistor that transfers charges generated by the first photoelectric conversion unit to the charge accumulation region,
in the first transfer transistor,
the first channel formation region is formed in a region between the first photoelectric conversion unit and the charge accumulation region of the semiconductor substrate on a first surface side that is a surface opposite to a light receiving surface of the semiconductor substrate,
the first gate electrode is formed on the first surface of the semiconductor substrate via the first gate insulating film so as to face the first channel formation region,
the second transistor is a second transfer transistor that transfers charges generated by the second photoelectric conversion unit to the charge accumulation region,
in the second transfer transistor,
the second channel formation region is formed in a region between the second photoelectric conversion unit and the charge accumulation region of the semiconductor substrate on the first surface side of the semiconductor substrate,
the second gate electrode is formed on the first surface of the semiconductor substrate via the second gate insulating film so as to face the second channel formation region, and
further, a thickness of a band-shaped region of the first gate insulating film extending from the first photoelectric conversion unit side to the charge accumulation region side is smaller than a thickness of each portion of the second gate insulating film in a case of being viewed from a thickness direction of the semiconductor substrate.

4. The photodetection device according to claim 3, wherein
thicknesses of remaining regions of the first gate insulating film located on one side and another side sandwiching the band-shaped region are larger than the thickness of the band-shaped region.

5. The photodetection device according to claim 3, wherein
the first gate electrode and the second gate electrode are continuous.

6. The photodetection device according to claim 5, further comprising a pixel isolation portion formed in a region between the photoelectric conversion units adjacent to each other in the semiconductor substrate, wherein
the pixel isolation portion includes a p-type semiconductor region,
the charge accumulation region is formed in a region located at a center of a block constituted by 2×2 photoelectric conversion units in the pixel isolation portion and is shared by the 2×2 photoelectric conversion units in a case of being viewed from the thickness direction of the semiconductor substrate,
the first photoelectric conversion unit and the second photoelectric conversion unit are a pair of adjacent photoelectric conversion units included in the 2×2 photoelectric conversion units, and
each of the first gate insulating film and the second gate insulating film, and the first gate electrode and the second gate electrode is continuously formed across a region located between the first photoelectric conversion unit and the second photoelectric conversion unit in the pixel isolation portion in a case of being viewed from the thickness direction of the semiconductor substrate.

7. The photodetection device according to claim 6, further comprising a trench portion formed at a center in a width direction of the pixel isolation portion, and an insulating film embedded in the trench portion.

8. The photodetection device according to claim 2, further comprising a wiring layer arranged on a first surface opposite to a light receiving surface of the semiconductor substrate, wherein
the first gate electrode and the second gate electrode are electrically connected via a wiring of the wiring layer.

9. The photodetection device according to claim 1, wherein
an impurity concentration of the first channel formation region is lower than an impurity concentration of the second channel formation region such that a difference between the first voltage and the second voltage is equal to or larger than a predetermined value.

10. The photodetection device according to claim 9, further comprising a charge accumulation region formed on the semiconductor substrate apart from the photoelectric conversion units and shared by two or more of the photoelectric conversion units, wherein
the two or more photoelectric conversion units include a first photoelectric conversion unit and a second photoelectric conversion unit adjacent to each other,
the first transistor is a first transfer transistor that transfers charges generated by the first photoelectric conversion unit to the charge accumulation region,
in the first transfer transistor,
the first channel formation region is formed in a region between the first photoelectric conversion unit and the charge accumulation region of the semiconductor substrate on a first surface side that is a surface opposite to a light receiving surface of the semiconductor substrate,
the first gate electrode is formed on the first surface of the semiconductor substrate via a first gate insulating film so as to face the first channel formation region,
the second transistor is a second transfer transistor that transfers charges generated by the second photoelectric conversion unit to the charge accumulation region,
in the second transfer transistor,
the second channel formation region is formed in a region between the second photoelectric conversion unit of the semiconductor substrate and the charge accumulation region on the first surface side of the semiconductor substrate, and
the second gate electrode is formed on the first surface of the semiconductor substrate via a second gate insulating film so as to face the second channel formation region.

11. The photodetection device according to claim 10, wherein
the first gate electrode and the second gate electrode are continuous.

12. The photodetection device according to claim 11, further comprising a pixel isolation portion formed in a region between the photoelectric conversion units adjacent to each other in the semiconductor substrate, wherein
the pixel isolation portion includes a p-type semiconductor region,
the charge accumulation region is formed in a region located at a center of a block constituted by 2×2 photoelectric conversion units in the pixel isolation portion and is shared by the 2×2 photoelectric conversion units in a case of being viewed from a thickness direction of the semiconductor substrate,
the first photoelectric conversion unit and the second photoelectric conversion unit are a pair of adjacent photoelectric conversion units included in the 2×2 photoelectric conversion units, and
each of the first gate insulating film and the second gate insulating film, and the first gate electrode and the second gate electrode is continuously formed across a region located between the first photoelectric conversion unit and the second photoelectric conversion unit in the pixel isolation portion in a case of being viewed from the thickness direction of the semiconductor substrate.

13. The photodetection device according to claim 12, further comprising a trench portion formed at a center in a width direction of the pixel isolation portion, and an insulating film buried in the trench portion.

14. The photodetection device according to claim 9, further comprising a wiring layer arranged on a first surface opposite to a light receiving surface of the semiconductor substrate, wherein
the first gate electrode and the second gate electrode are electrically connected via a wiring of the wiring layer.

15. Electronic equipment comprising a photodetection device that includes a semiconductor substrate, a plurality of photoelectric conversion units formed in a two-dimensional array on the semiconductor substrate, and a plurality of pixel transistors, wherein
a plurality of the pixel transistors includes a first transistor having a first gate electrode facing a first channel formation region, and a second transistor having a second gate electrode facing a second channel formation region and electrically connected to the first gate electrode, in a case where a first voltage is applied to the first gate electrode and the second gate electrode, a channel is formed only in the first channel formation region, and in a case where a second voltage higher than the first voltage is applied to the first gate electrode and the second gate electrode, a channel is formed in both the first channel formation region and the second channel formation region.

16. A semiconductor device comprising:
a first transistor having a first gate electrode facing a first channel formation region; and
a second transistor having a second gate electrode facing a second channel formation region and electrically connected to the first gate electrode, wherein
in a case where a first voltage is applied to the first gate electrode and the second gate electrode, a channel is formed only in the first channel formation region, and in a case where a second voltage higher than the first voltage is applied to the first gate electrode and the second gate electrode, a channel is formed in both the first gate electrode and the second channel formation region.
